(19) United States
(12) Patent Application Publication
(10) Pub. No.: US 2025/0022945 A1
(43) Pub. Date: Jan. 16, 2025

(54) SEMICONDUCTOR DEVICE HAVING NANOSTRUCTURE TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Chung-En TSAI, Hsinchu (TW); Sheng-Syun WONG, Hsinchu (TW); Cheng-Han LEE, New Taipei City (TW); Chih-Yu MA, Hsinchu (TW); Shih-Chieh CHANG, Taipei City (TW)

(21) Appl. No.: 18/222,124

(22) Filed: Jul. 14, 2023

(51) Int. Cl. H01L 29/775; H01L 29/06; H01L 29/08; H01L 29/417; H01L 29/423; H01L 29/66

(52) U.S. Cl. CPC H01L 29/775; H01L 29/0673; H01L 29/0847; H01L 29/41775; H01L 29/42392; H01L 29/66439; H01L 29/66545; H01L 29/66553

(57) ABSTRACT

Various embodiments of the present disclosure provide a semiconductor device structure. In one embodiment, the semiconductor device structure includes a first source/drain feature and a second source/drain feature, a plurality of semiconductor layers vertically stacked and disposed between the first and second source/drain features, a gate electrode layer surrounding a portion of each of the plurality of the semiconductor layers, and an interfacial layer (IL) disposed between the gate electrode layer and one of the plurality of the semiconductor layers, wherein a topmost semiconductor layer of the plurality of the semiconductor layers has a first length, and the IL has a second length greater than the first length.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down presents new challenge. For example, transistors using nanostructure channels have been proposed to improve carrier mobility and drive current in a device. An inner spacer is often disposed between metal gate and source/drain (S/D) structure to protect the S/D structure during the subsequent gate replacement process. Although the formation of the inner spacer has been generally adequate for their intended purposes, the S/D structure may still suffer from damage due to etchant leakage during the gate replacement process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure in accordance with some embodiments.

FIGS. 6A-19A are cross-sectional side views of various stages of manufacturing the semiconductor device structure taken along cross-section A-A of FIG. 5, in accordance with some embodiments.

FIGS. 6B-19B are cross-sectional side views of various stages of manufacturing the semiconductor device structure taken along cross-section B-B of FIG. 5, in accordance with some embodiments.

FIGS. 6C and 14C-19C are cross-sectional side views of various stages of manufacturing the semiconductor device structure taken along cross-section C-C of FIG. 5, in accordance with some embodiments.

FIGS. 6D and 14D-19D are cross-sectional side views of various stages of manufacturing the semiconductor device structure taken along cross-section D-D of FIG. 5, in accordance with some embodiments.

FIG. 7A-1 illustrates an enlarged view of a portion of the semiconductor device structure, in accordance with some embodiments.

FIG. 12A-1 illustrates an enlarged view of a portion of the semiconductor device structure of FIG. 12A, in accordance with some embodiments.

FIGS. 14A-1 and 14B-1 are enlarged views of a portion of the semiconductor device structure of FIGS. 14A and 14B, in accordance with some embodiments.

FIG. 14E illustrates a top view of a portion of the semiconductor device structure taken along cross-section E-E of FIG. 14A, in accordance with some embodiments.

FIG. 14F illustrates a top view of a portion of the semiconductor device structure taken along cross-section F-F of FIG. 14A, in accordance with some embodiments.

FIG. 18A-1 illustrates an enlarged view of a portion of the semiconductor device structure of FIG. 18A, in accordance with some embodiments.

FIG. 18A-2 illustrates an enlarged view of a portion of the semiconductor device structure of FIG. 18A-1, in accordance with some embodiments.

FIG. 18E illustrates a top view of a portion of the semiconductor device structure taken along cross-section E-E of FIG. 18A, in accordance with some embodiments.

FIG. 18F illustrates a top view of a portion of the semiconductor device structure taken along cross-section F-F of FIG. 18A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

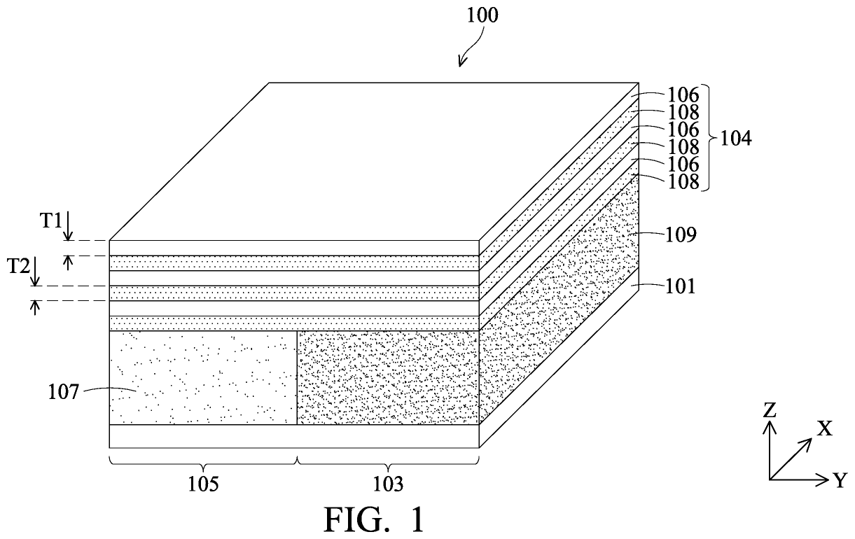

FIGS. 1 to 19D show exemplary processes for manufacturing a semiconductor device structure 100 according to embodiments of the present disclosure. It is understood that additional operations can be provided before, during, and after processes shown by FIGS. 1 to 19D, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 in accordance with some embodiments. With reference to FIG. 1, the semiconductor device structure 100 is illustrated to include a substrate 101 into which dopants have been implanted in order to form wells. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 includes a first device region 103 for forming N-type devices, such as NMOS devices (e.g., N-type gate all around transistors) and a second device region 105 for forming P-type devices, such as PMOS devices (e.g., P-type gate all around transistors). To separate the first device region 103 and the second device region 105, wells may be formed within the substrate 101 with N-type dopants and P-type dopants. To form the desired wells, the N-type dopants and the P-type dopants are implanted into the substrate 101 depending upon the devices to be formed. For example, N-type dopants such as phosphorous or arsenic may be implanted to form N-type wells, while P-type dopants such as boron may be implanted to form P-type wells. The N-type wells and P-type wells may be formed using one or more implantation techniques, such as diffusion implantations, ion implantations (e.g., plasma doping, beam line implant doping), selective implantations, deep-well implantations, and the like, or combinations thereof. Masking techniques may also be utilized to mask some regions (e.g., second device region 105) of the substrate 101 while exposing other regions (e.g., first device region 103) of the substrate 101 during a first well implantation (e.g., N-type wells) process. Once the first well implantation process has been completed, the mask is removed to expose the previously masked regions (e.g., second device region 105) and another mask may be placed over the previously exposed regions (e.g., first device region 103) during a second well implantation (e.g., P-type wells) process. In one embodiment shown in FIG. 1, the substrate 101 includes an N-type well 107 and an P-type well 109. While the first device region 103 is shown adjacent to the second device region 105, it is understood that the first device region 103 may be disposed away from the second device region 105 at different regions of the substrate 101 along the X direction or Y direction, and the first and second device regions 103, 105 belong to a continuous substrate (e.g., substrate 101).

FIG. 1 also illustrates a stack of semiconductor layers 104 formed over the substrate 101 at the first and second device regions 103, 105. The stack of semiconductor layers 104 includes semiconductor layers made of different materials to facilitate formation of nanostructure channels in a multi-gate device, such as nanostructure FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The thickness of the first semiconductor layers 106 and the second semiconductor layers 108 may vary depending on the application and/or device performance considerations. In some embodiments, each first and second semiconductor layer 106, 108 has a thickness T1. T2 of about 2 nm to about 30 nm, respectively. In other embodiments, each first and second semiconductor layer 106, 108 has a thickness T1, T2 of about 10 nm to about 20 nm. The thickness T1 of the first semiconductor layer 106 may be equal to, less than, or greater than the thickness of the thickness T2 of the second semiconductor layer 108. The second semiconductor layers 108 may eventually be removed and serve to define a vertical distance between adjacent channels for the semiconductor device structure 100.

The first semiconductor layers 106 or portions thereof may form nanostructure channel(s) of the semiconductor device structure 100 in later fabrication stages. The term “nanostructure” is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanowire transistors, nanosheet transistors, gate-all-around (GAA) transistors, multi-bridge channel (MBC) transistors, or any transistors having the gate electrode surrounding the channels. The use of the first semiconductor layers 106 to define channels of the semiconductor device structure 100 is further discussed below.

The first and second semiconductor layers 106, 108 are formed by any suitable deposition process, such as epitaxy. By way of example, epitaxial growth of the layers of the stack of semiconductor layers 104 may be performed by a vapor-phase epitaxy (VPE), a molecular beam epitaxy (MBE) process, a metalorganic chemical vapor deposition (MOCVD) process, and/or other suitable growth processes, such as chemical vapor deposition (CVD), low pressure CVD (LPCVD), atomic layer CVD (ALCVD), ultra-high vacuum CVD (UHVCVD), reduced pressure CVD (RPCVD), a combination thereof, or the like. While three first semiconductor layers 106 and three second semiconductor layers 108 are alternately arranged as illustrated in FIG. 1, any number of first and second semiconductor layers 106, 108 can be formed in the stack of semiconductor layers 104, depending on the predetermined number of nanostructure channels for each FET. For example, the number of first semiconductor layers 106, which is the number of channels, may be between 2 and 8.

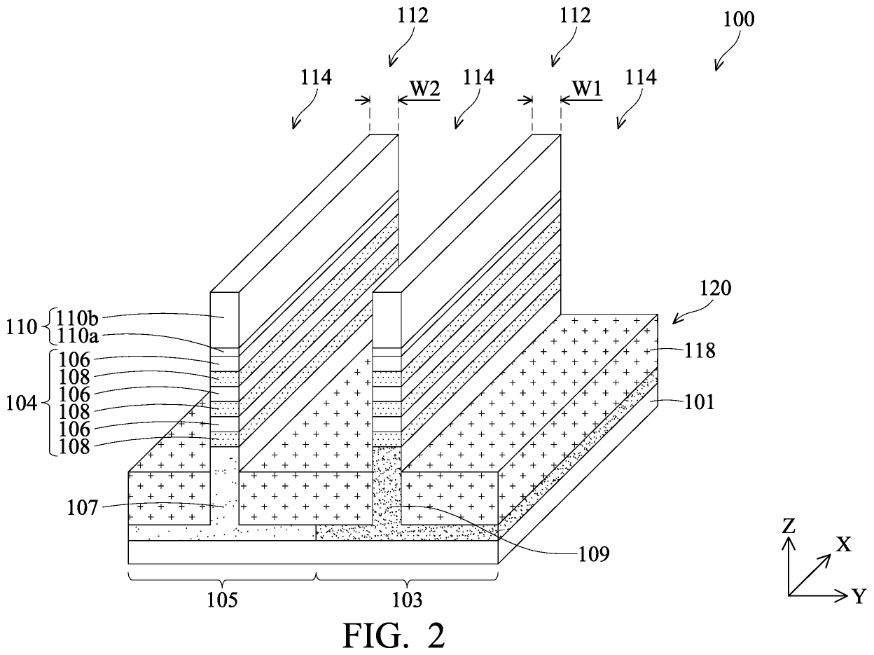

In FIG. 2, fin structures 112 are formed from the stack of semiconductor layers 104, and an insulating material 118 is formed in the trenches 114 between the fin structures 112. Each fin structure 112 has a portion including the semiconductor layers 106, 108, a portion of the wells 107, 109, and a portion of a mask structure 110. The mask structure 110 is formed over the stack of semiconductor layers 104 prior to forming the fin structures 112. The mask structure 110 may include a pad layer 110a and a hard mask 110b. The pad layer 110a may be an oxygen-containing layer. The hard mask 110b may be a nitrogen-containing layer. The fin structures 112 may be fabricated using suitable processes including photolithography and etch processes. In some embodiments, the photolithography process may include forming a photoresist layer (not shown) over the mask structure 110, exposing the photoresist layer to a pattern, performing post-exposure bake processes, and developing the photoresist layer to form a patterned photoresist layer. The patterned photoresist layer may then be used to protect regions of the substrate 101 and layers formed thereupon, while an etch process forms trenches 114 in unprotected regions through the mask structure 110, the stack of semiconductor layers 104, and into the wells 107, 109 of the substrate 101, thereby forming the extending fin structures 112. A width W1 of the fin structures 112 at the first device region 103 along the Y direction may be in a range between about 3 nm and about 44 nm. A width W2 of the fin structures 112 at the second device region 105 along the Y direction may be equal to, less than, or greater than the width W1. The trenches 114 may be etched using a dry etch (e.g., RIE), a wet etch, and/or combination thereof. While two fin structures 112 are shown, the number of the fin structures is not limited to two.

After the fin structures 112 are formed, the insulating material 118 is formed in the trenches 114 between the fin structures 112. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as LPCVD, plasma enhanced CVD (PECVD) or flowable CVD (FCVD). Next, the insulating material 118 is recessed to form an isolation region 120. The recess of the insulating material 118 exposes portions of the fin structures 112. The isolation region 120 may be formed using a suitable process, such as a dry etching process, a wet etching process, or a combination thereof. A top surface of the insulating material 118 may be level with or below a surface of the second semiconductor layer 108 in contact with the wells 107, 109.

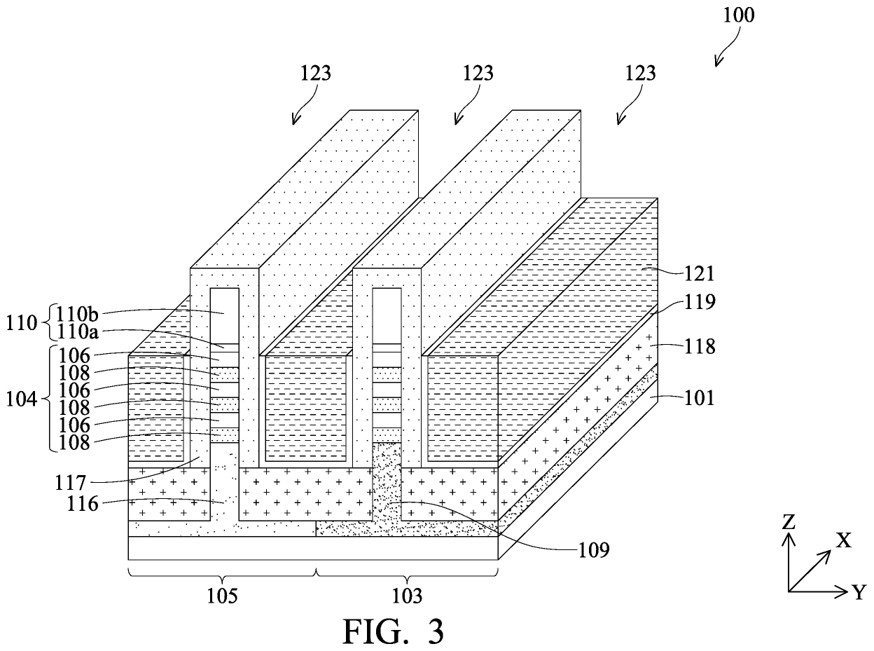

In FIG. 3, a cladding layer 117 is formed over exposed portion of the fin structures 112. The cladding layer 117 is in contact with the stack of semiconductor layers 104. In some embodiments, the cladding layer 117 and the second semiconductor layers 108 include the same material. For example, the cladding layer 117 and the second semiconductor layers 108 may be or include SiGe. The cladding layer 117 and the second semiconductor layers 108 are to be removed subsequently to create space for the subsequently formed gate electrode layer. A liner 119 is formed on the cladding layer 117 and the top surface of the insulating material 118. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 2) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112 (FIG. 2).

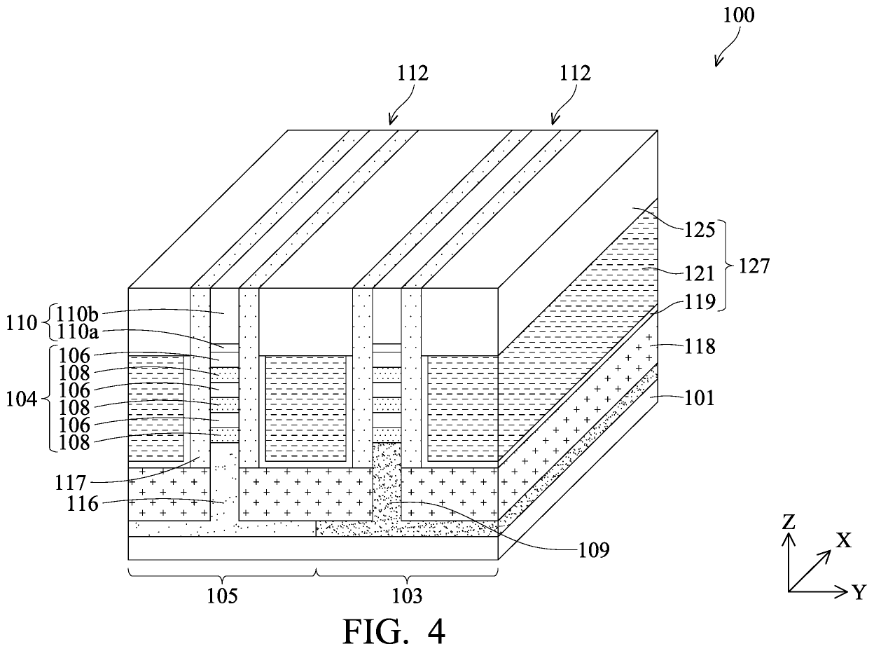

In FIG. 4, a dielectric material 125 is formed in the trenches 123 (FIG. 3) and on the dielectric material 121 and the liner 119. The dielectric material 125 may include SiO, SiN, SiC, SiCN, SiON, SiOCN, AlO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequently formed source/drain (S/D) epitaxial features and adjacent gate electrode layers.

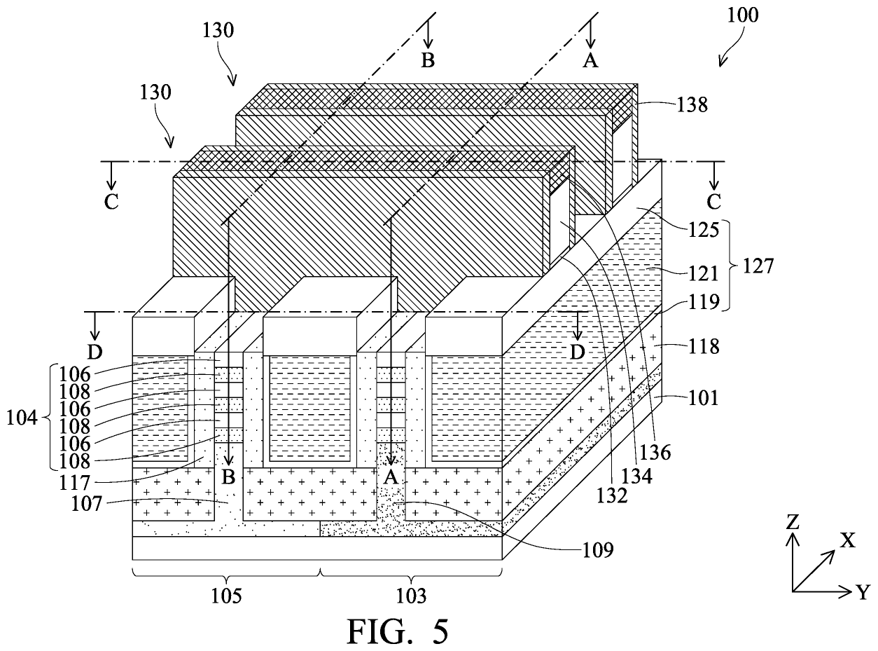

In FIG. 5, the cladding layers 117 are recessed, and the mask structures 110 are removed. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

Thereafter, one or more sacrificial gate structures 130 are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. While two sacrificial gate structures 130 are shown, three or more sacrificial gate structures 130 may be arranged along the X direction in some embodiments.

FIG. 5 also illustrates that gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100 by an ALD process or any suitable conformal deposition technique. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as SiO₂, Si₃N₄, SiC, SiON, SiCN, SiOCN, carbon doped oxide, nitrogen doped oxide, porous oxide, air gaps, and/or combinations thereof.

It should be understood that the cladding layers 117 and dielectric feature 127 (i.e., hybrid fin) are optional and may not be needed. In some embodiments where the cladding layers 117 and the dielectric features 127 are not present, portions of the sacrificial gate structures 130 and the gate spacers 138 are formed on the fin structures 112 and the insulating material 118, and gaps are formed between exposed portions of the fin structures 112.

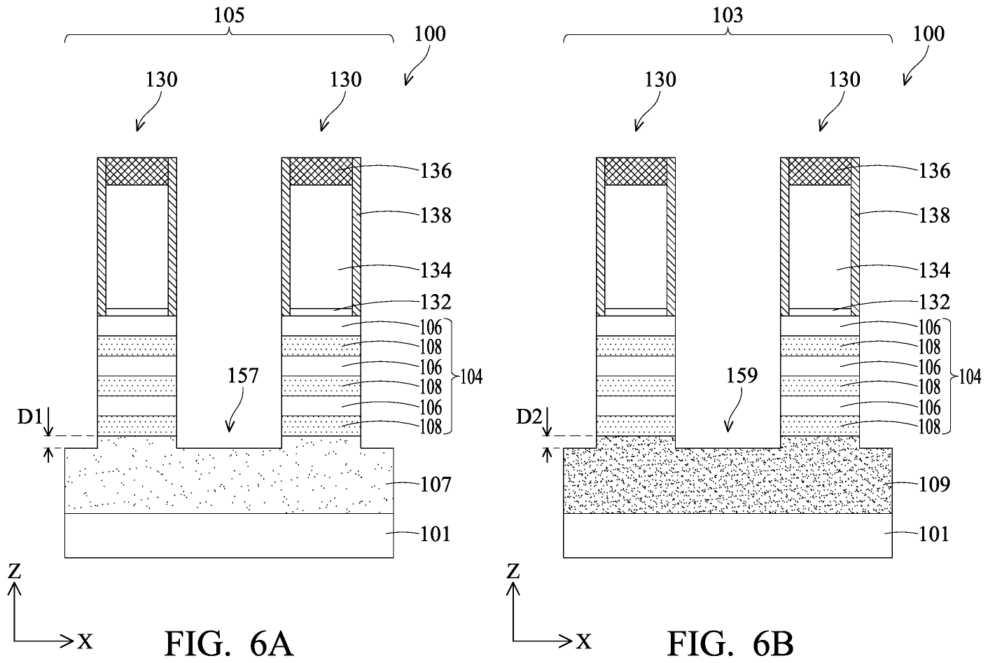

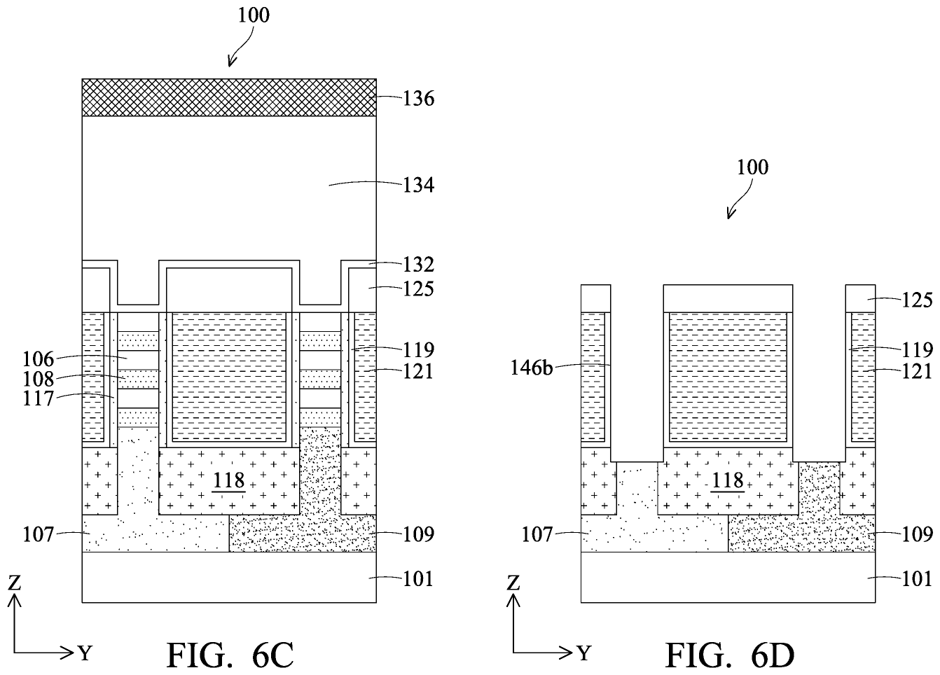

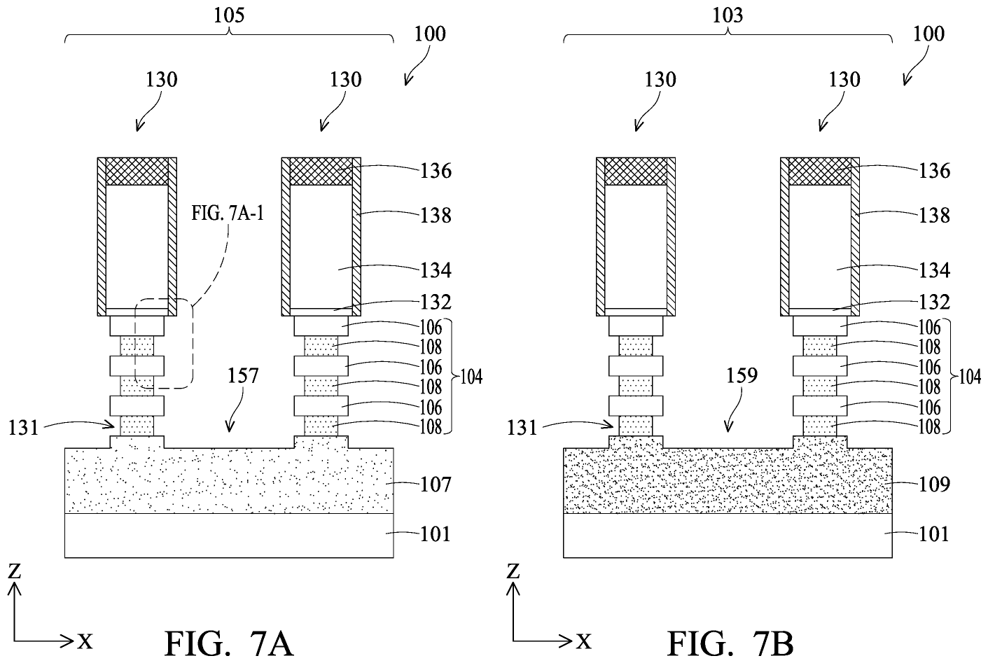

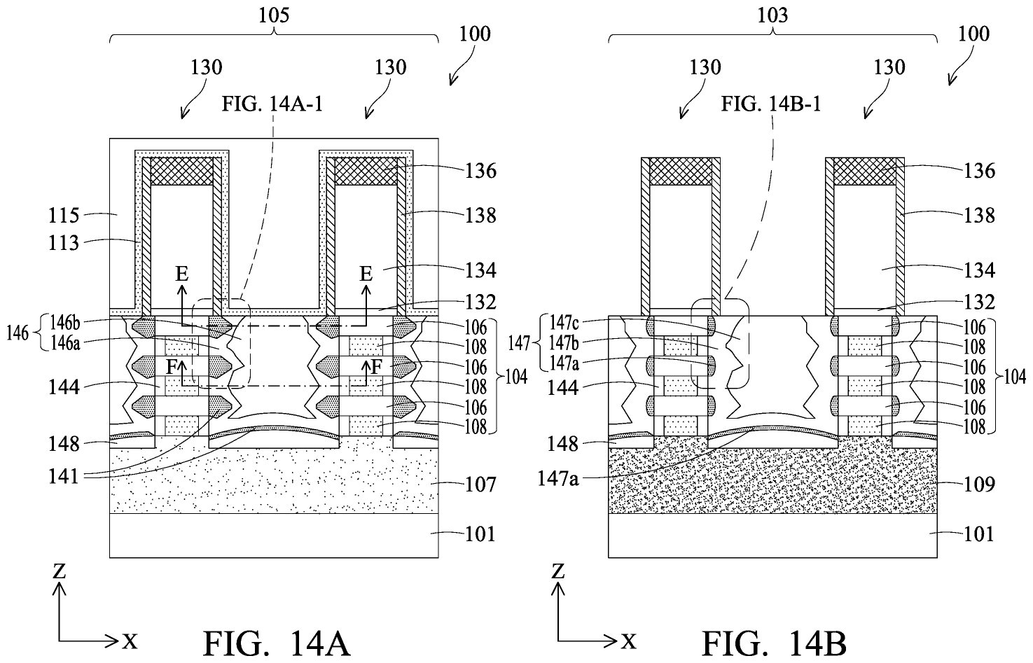

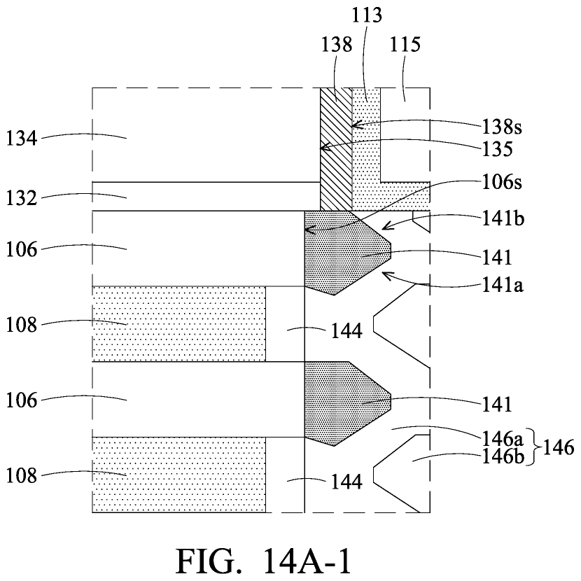

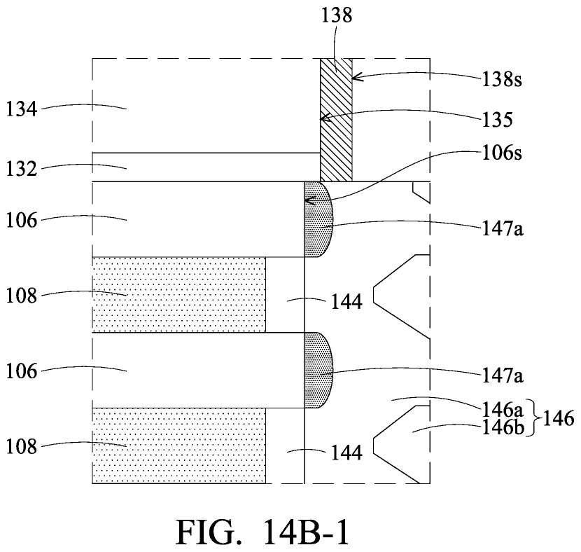

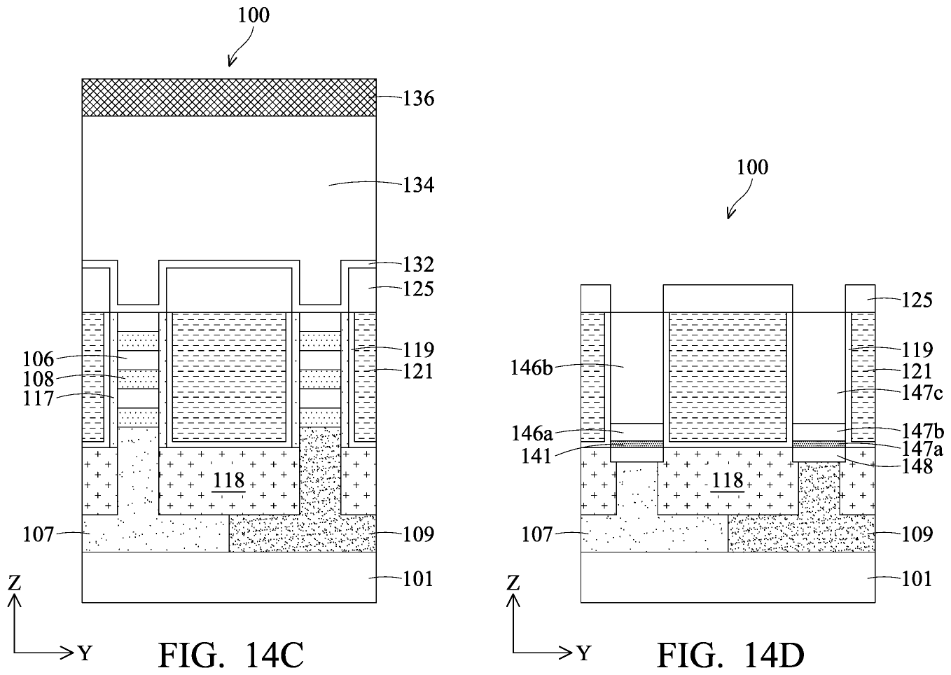

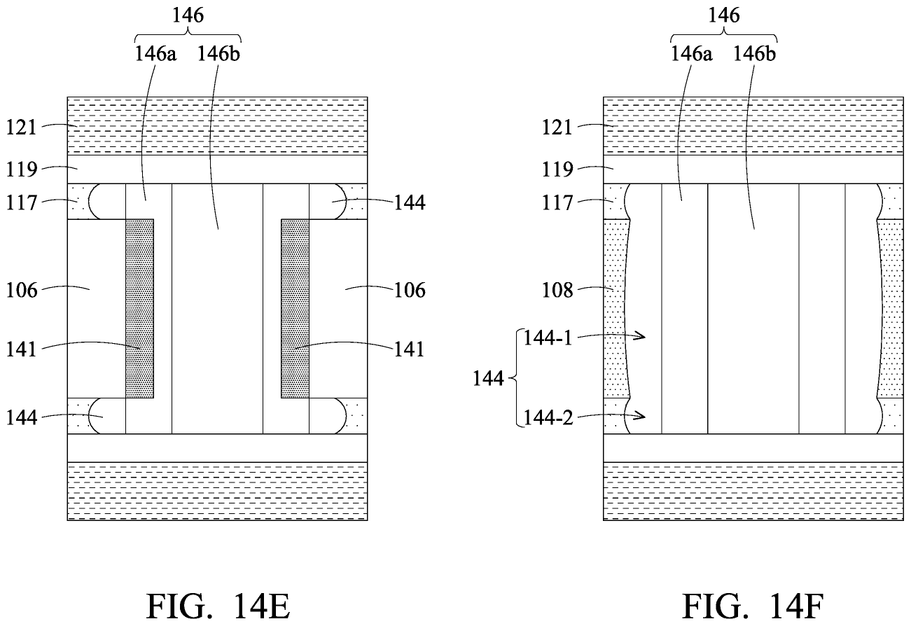

FIGS. 6A-19A are cross-sectional side views of various stages of manufacturing the semiconductor device structure 100 taken along cross-section A-A of FIG. 5, in accordance with some embodiments. FIGS. 6B-19B are cross-sectional side views of various stages of manufacturing the semiconductor device structure 100 taken along cross-section B-B of FIG. 5, in accordance with some embodiments. FIGS. 6C and 14C-19C are cross-sectional side views of various stages of manufacturing the semiconductor device structure 100 taken along cross-section C-C of FIG. 5, in accordance with some embodiments. FIGS. 6D and 14D-19D are cross-sectional side views of various stages of manufacturing the semiconductor device structure 100 taken along cross-section D-D of FIG. 5, in accordance with some embodiments. Cross-sections A-A and B-B are in a plane of the fin structure 112 (FIG. 4) along the X direction. Cross-section C-C is in a plane perpendicular to cross-section A-A and is in the sacrificial gate structure 130. Cross-section D-D is in a plane perpendicular to cross-section A-A and is in the S/D features 146 (FIGS. 14A and 14B) along the Y-direction.

In FIGS. 6A-6D, exposed portions of the fin structures 112, exposed portions of the cladding layers 117, and exposed portions of the dielectric material 125 at the first and second device regions 103, 105 not covered by the sacrificial gate structures 130 and the gate spacers 138 are selectively recessed by one or more suitable etch processes, such as dry etch, wet etch, or a combination thereof. The portions of the fin structures 112, exposed portions of the cladding layers 117, exposed portions of the dielectric material 125, and a portion of the wells 107, 109 are removed to expose the sidewalls of the fin structures 112 (FIG. 4). In some embodiments, the exposed portions of the fin structures 112 are recessed to a level at or slightly below a bottom surface of the second semiconductor layer 108 in contact with the wells 107, 109 of the substrate 101, respectively. Therefore, the sidewall of the bottommost second semiconductor layer 108 of each fin structure 112 is fully exposed. In some embodiments, the removal process includes two etch processes, in which a first etch process is performed to remove the exposed portions of the stacks of semiconductor layers 104 of the fin structures 112, the cladding layers 117, and the dielectric material 125, and expose portions of the wells 107, 109, and a second etch process is performed to remove the exposed portions of the wells 107, 109. The removal of the portions of the wells 107, 109 results in recesses 157, 159 formed in the top portion of the bulk silicon region (e.g., wells 107, 109), while the top portion of the bulk silicon region under the sacrificial gate structure 130 is covered and not removed. As a result of the removal of the portions of the wells 107, 109, a top surface of the exposed wells 107, 109 is at a level lower than an interface defined between the bottommost second semiconductor layer 108 and the wells 107, 109 by a distance D1, D2, respectively. In some embodiments, the distance D1 and D2 is in a range from about 5 nm to about 30 nm.

In some embodiments, the removal process is performed such that the exposed wells 109 (e.g., N-type wells) at the second device region 105 are etched deeper than the exposed wells 107 (e.g., P-type wells). As channel mobility of PMOS devices (e.g., P-type gate all around transistors) is closely correlated to the dimension of source/drain (S/D) features, having the greater amount of the exposed wells 109 removed can result in the subsequent S/D features 147 (FIG. 14B) formed with greater volume, and therefore higher strain effects for PMOS devices ion improvement. In such a case, the distance D2 may be greater than the distance D1 by, for example, about 3 nm to about 15 nm.

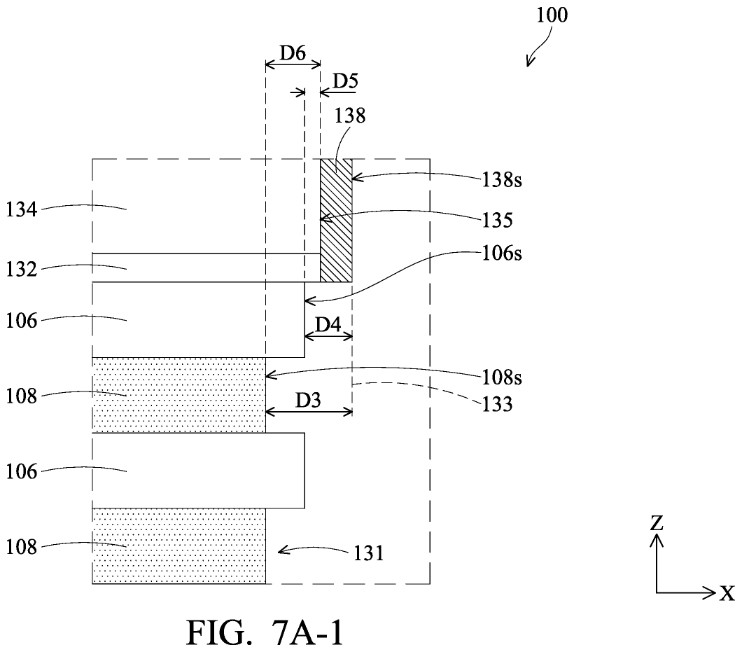

In FIGS. 7A and 7B, edge portions of each second semiconductor layer 108 of the stack of semiconductor layers 104 are removed horizontally along the X direction. During the removal of the second semiconductor layers 108, portions of the first semiconductor layers 106 is also horizontally removed. Alternatively, a first etch process may be performed to remove a portion of both the first and second semiconductor layers 106, 108, and a second etch process may be performed to further remove a portion of the first semiconductor layers 106 so that an interface 135 defined by the gate spacer 138 and the sacrificial gate electrode layer 134 (or the sacrificial gate dielectric layer 132) is exposed, as shown in FIG. 7A-1. In some embodiments, a single prolonged etch process may be performed to remove portions of both the first and second semiconductor layers 106, 108 until the interface 135 is exposed.

FIG. 7A-1 shows an enlarged view of a portion of the semiconductor device structure 100 in accordance with some embodiments. As can be seen, the second semiconductor layer 108 may be removed by a lateral distance D3 measuring from an edge (e.g., sidewall 108s) of the second semiconductor layer 108 to an imaginary line 133 extending downwardly from a sidewall 138s of the gate spacer 138, and the first semiconductor layer 106 may be removed by a lateral distance D4 measuring from an edge (e.g., sidewall 106s) of the first semiconductor layer 106 to the imaginary line 133 extending downwardly from the sidewall of the gate spacer 138. In various embodiments, the distance D4 is greater than the distance D3. In other words, the recessed amount of the second semiconductor layers 108 is greater than the recessed amount of the first semiconductor layers 106. The removal of the edge portions of the second semiconductor layers 108 forms cavities 131.

The portions of the first and second semiconductor layers 106, 108 may be removed by a selective wet etching process or other suitable removal process. In cases where the second semiconductor layers 108 are made of SiGe and the first semiconductor layers 106 are made of silicon, the second semiconductor layer 108 can be selectively etched using an etchant such as, but not limited to, HF:HNO₃ solution, ammonium hydroxide (NH₄OH) and H₂O₂ solution, tetramethylammonium hydroxide (TMAH) solution, ethylenediamine pyrocatechol (EDP), potassium hydroxide (KOH) solutions, or HF:H₂O₂:CH₃COOH. Since the first semiconductor layers 106 and the second semiconductor layers 108 are made of different materials having different etch selectivity, the etchant may etch the second semiconductor layers 108 at a faster rate than the first semiconductor layers 106, resulting in an etch profile shown in FIGS. 7A and 7B. The etchant may also be configured and/or work with different etching times to promote etching of SiGe at a greater amount than silicon.

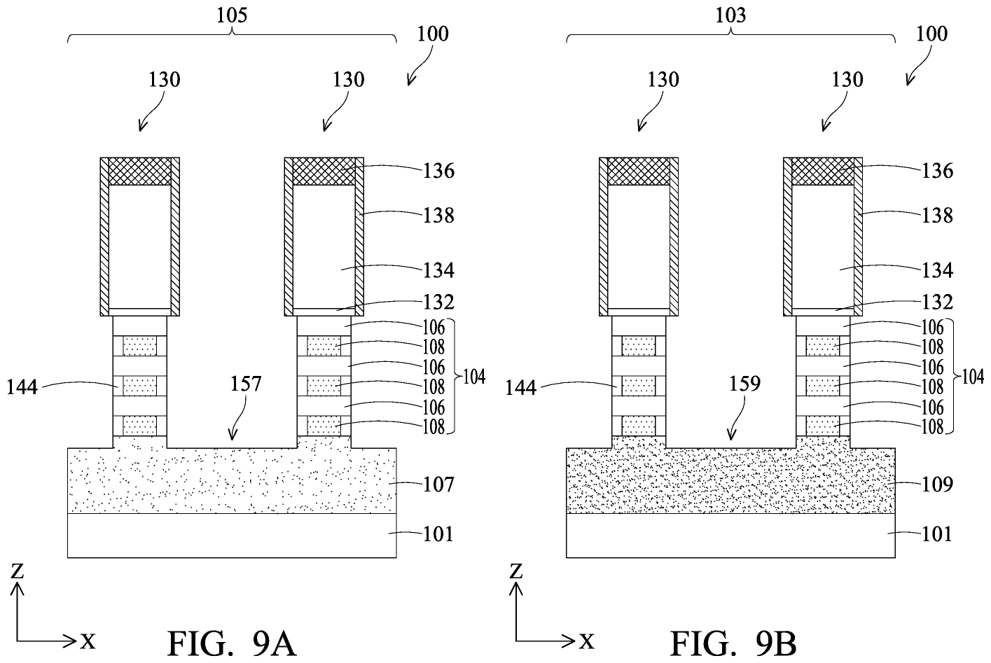

Referring to FIG. 7A-1, the first semiconductor layers 106 are etched such that the sidewall 106s of the first semiconductor layer 106 is recessed from the interface 135 defined by the gate spacer 138 and the sacrificial gate electrode layer 134 (or the sacrificial gate dielectric layer 132) by a distance D5. In various embodiments, the distance D5 is less than the distance D4. The presence of the distance D5 ensures the subsequent blocking structure 141 (FIG. 14A-1) to extend over and fully cover the interface 135 (FIG. 14A-1), which may otherwise become a leakage path for the etchant used during the removal of the sacrificial gate structure 130. The semiconductor layers 108 are etched such that the sidewall 108s of the semiconductor layer 108 is recessed from the interface 135 by a distance D6. In various embodiments, the distance D6 is greater than the distance D5. The difference between the distance D5 and the distance D6 define the width of the inner spacer 144 (FIGS. 9A and 9B).

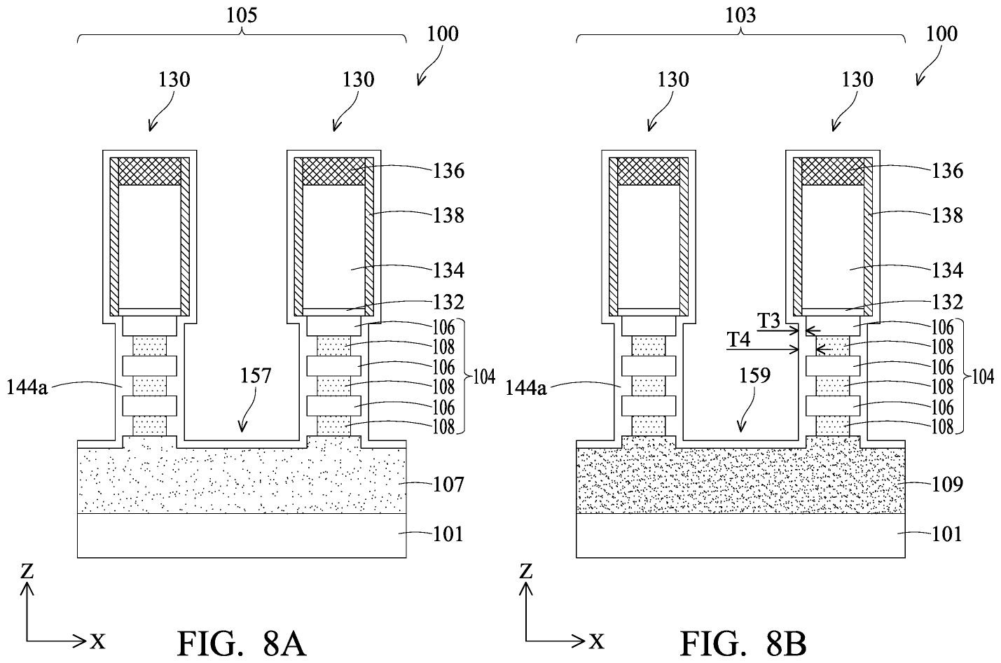

In FIGS. 8A and 8B, a dielectric layer 144a is conformally formed on the exposed surfaces of the sacrificial gate structures 130, the first semiconductor layers 106, the second semiconductor layers 108, and the exposed portions of the wells 107, 109 of the substrate 101. The dielectric layer 144a fills the cavities 131 (FIGS. 7A and 7B) formed as a result of the removal of the edge portions of the second semiconductor layers 108. The dielectric layer 144a may be made of a dielectric material. Suitable materials for the dielectric layer 144a may include, but are not limited to, SiO₂, Si₃N₄, SiC, SiCP, SION, SiOC, SiCN, SiOCN, and/or other suitable material. Other materials, such as low-k materials with a k value less than about 3.5, may also be used. The formation of the dielectric layer 144a may be formed by a conformal deposition process, such as ALD. The thickness T3 of the dielectric layer 144a adjacent the first semiconductor layers 106 (and wells 107, 109 of the substrate 101) may be in a range of about 1 nm to about 4 nm, while the thickness T4 of the dielectric layer 144a adjacent the second semiconductor layers 108 may be in a range of about 2 nm to about 10 nm. In some embodiments, the dielectric layer 144a is a single layer structure. In some embodiments, the dielectric layer 144 is a multi-layer structure using the material discussed herein.

In FIGS. 9A and 9B, portions of the dielectric layer 144a are removed and the portions of the dielectric layer 144a remain in the cavities 131 (FIGS. 7A and 7B) between the adjacent first semiconductor layers 106 to form inner spacers 144. In some embodiments, the dielectric layer 144a formed adjacent the sacrificial gate structures 130, the first semiconductor layers 106, and the wells 107, 109 of the substrate 101 are removed. The removal process may be performed until the first semiconductor layers 106 are exposed. For example, the duration of the removal process may be controlled so that the dielectric layer 144a on the exposed surfaces of the gate spacers 138, the sacrificial gate dielectric layers 132, and the first semiconductor layers 106 are removed. In some embodiments, the removal process is performed until at least the interface 135 (FIG. 7A-1) is fully exposed. The removal process may be any suitable etch processes, such as dry etch, wet etch, or a combination thereof. The etch process may use an etchant that selectively removes the dielectric layer 144a without substantially removing the gate spacers 138, the first and second semiconductor layers 106, 108. The removal of the portions of the dielectric layer 144a may be performed by an anisotropic etching. The dielectric layer 144a within the cavities 131 are protected by the first semiconductor layers 106 during the anisotropic etching process. The remaining second semiconductor layers 108 are capped between the inner spacers 144 along the X direction.

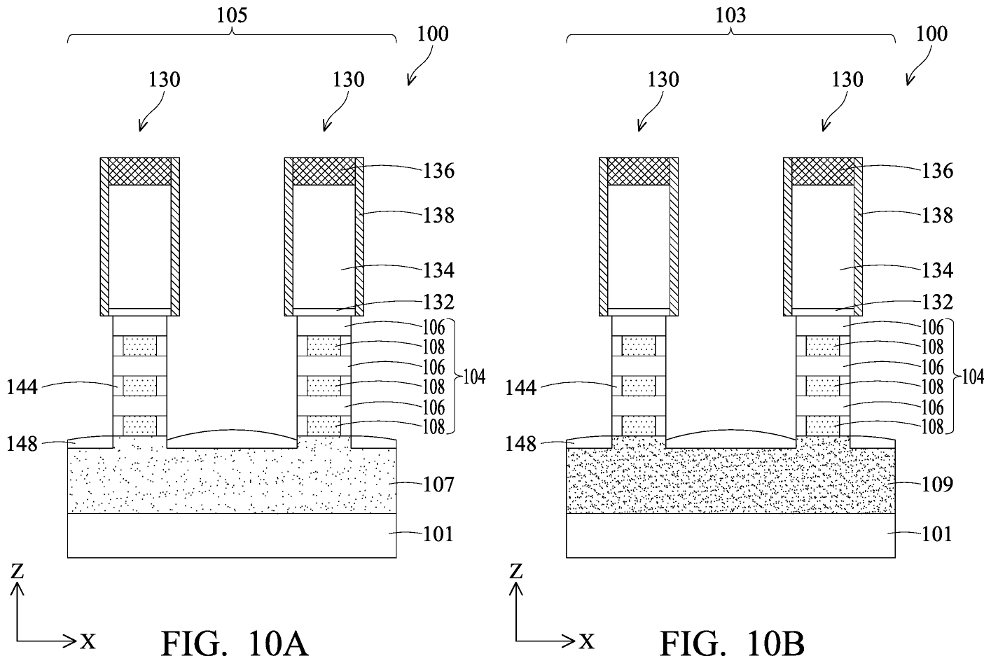

In FIGS. 10A and 10B, after the removal of portions of the dielectric layer 144a, an epitaxial layer 148 is formed on exposed surfaces (e.g., well portion 116) of the substrate 101 to promote epitaxial growth of subsequent S/D features 146. Therefore, the epitaxial layer 148 may be considered as a part of S/D feature 146. In some embodiments, a portion of the epitaxial layer 148 may be further formed on the exposed surfaces of the first semiconductor layers 106. The epitaxial layer 148 may be a dopant free semiconductor layer. The epitaxial layer 148 may be formed from other materials that is capable of providing structural transition and/or diffusion barrier, for example, the epitaxial layer 148 may include one or more layers of Si, Ge, SiGe, GaAs, InSb, GaP, GaSb, InAlAs, InGaAs, GaSbP, GaAsSb, and InP, depending on the material selection in the S/D features 146 and the subsequent layer. In one embodiment, the epitaxial layer 148 is a dopant free silicon layer, and may be formed using selective epitaxial growth (SEG), ALD, MBE, or any suitable growth process.

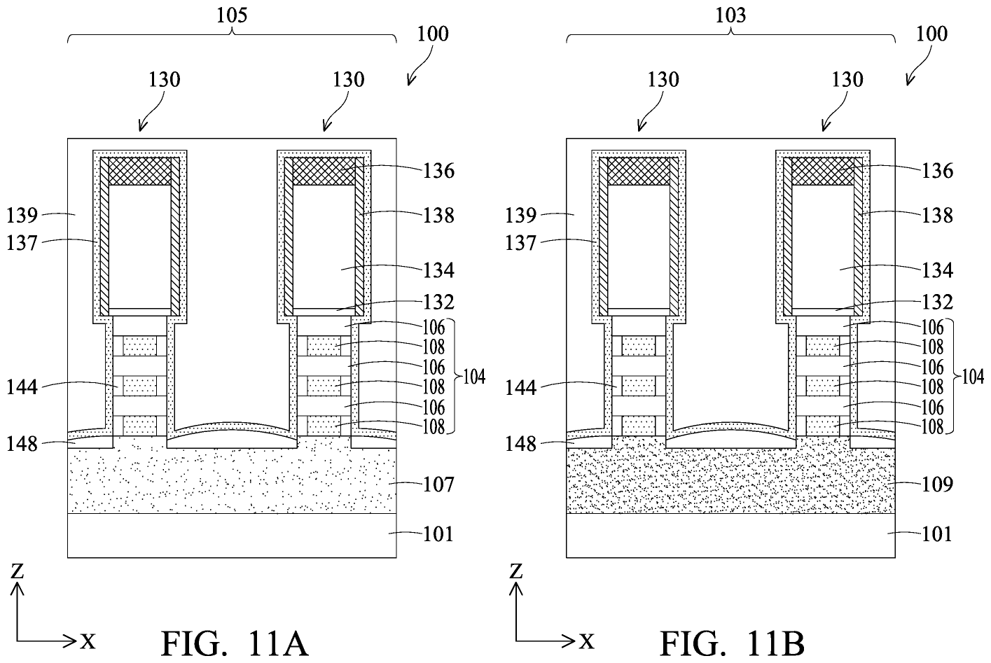

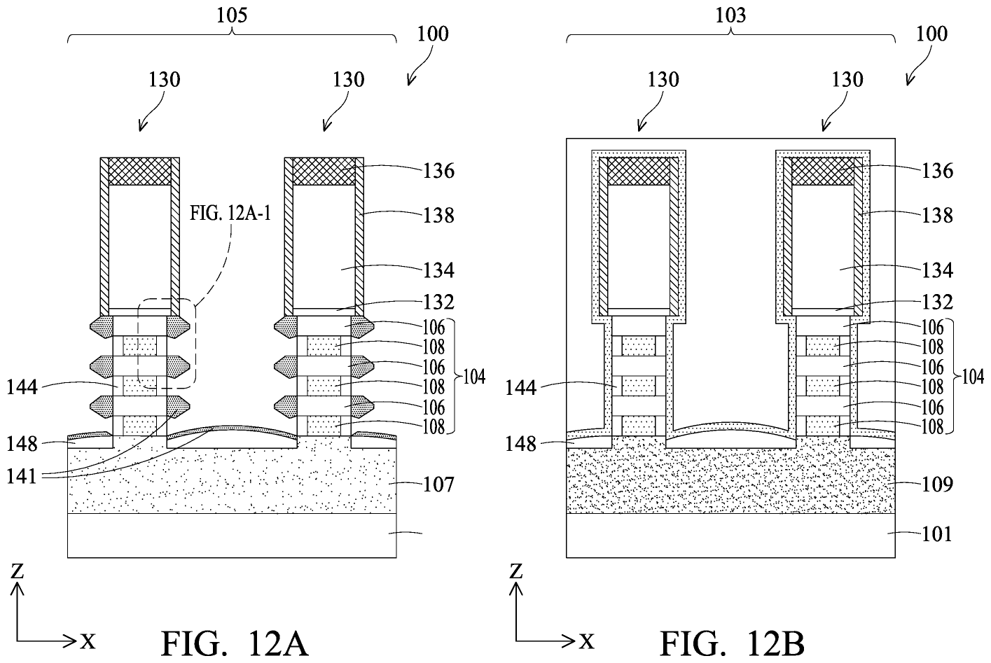

In FIGS. 11A and 11B, a hard mask layer 137 is deposited on exposed surfaces of the semiconductor device 100, and a photoresist layer 139 is formed on the hard mask layer 137. The hard mask layer 137 may be a conformal layer disposed on the exposed surfaces of the sacrificial gate structure 130, the first semiconductor layers 106, the inner spacer 144, and the epitaxial layer 148. The photoresist layer 139 may be deposited on the hard mask layer 137 until the sacrificial gate structures 130 are embedded within the photoresist layer 139. The hard mask layer 137 is to be patterned to subsequently processing areas for one type of devices, such as N-type devices in the first device region 103 or P-type devices in the second device region 105. In some embodiments, the hard mask layer 137 is an oxide, such as aluminum oxide (AlOₓ). Other suitable materials capable of withstanding the processing conditions of subsequent epitaxial source/drain formation and with an etch selectivity with a subsequently formed self-aligned mask may be used for the hard mask layer 137.

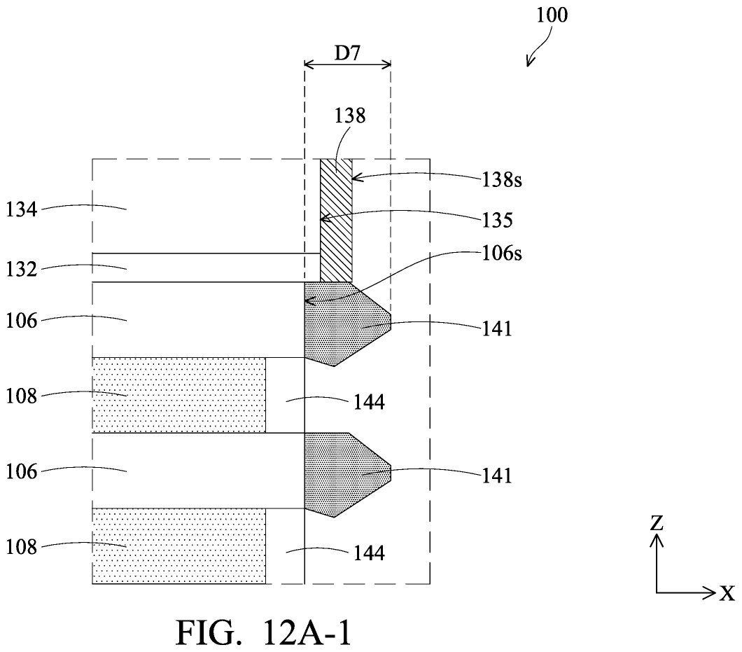

In FIGS. 12A and 12B, a photolithography process is performed to pattern the photoresist layer 139 to expose processing areas for one type of devices, such as N-type device areas or P-type device areas. The first device area 103 remains protected by the hard mask layer 137 and the photoresist layer 139. In one exemplary embodiment, the photoresist layer 139 at the second device region 105 is patterned to expose areas over the N-type well 107 where P-type devices are to be formed. The photoresist layer 139 may be removed by any suitable process, such as a wet strip process. After the photolithography process, an etch process is performed to remove the portion of the hard mask layer 137 at the second device region 105. The etch process to remove the portion of the hard mask layer 137 may include a wet etch process, exposing the processing areas for one type of devices, such as P-type device areas. A blocking structure 141 doped with P-type dopants (e.g., boron) is then formed on the exposed surfaces of the first semiconductor layers 106 and the epitaxial layer 148.

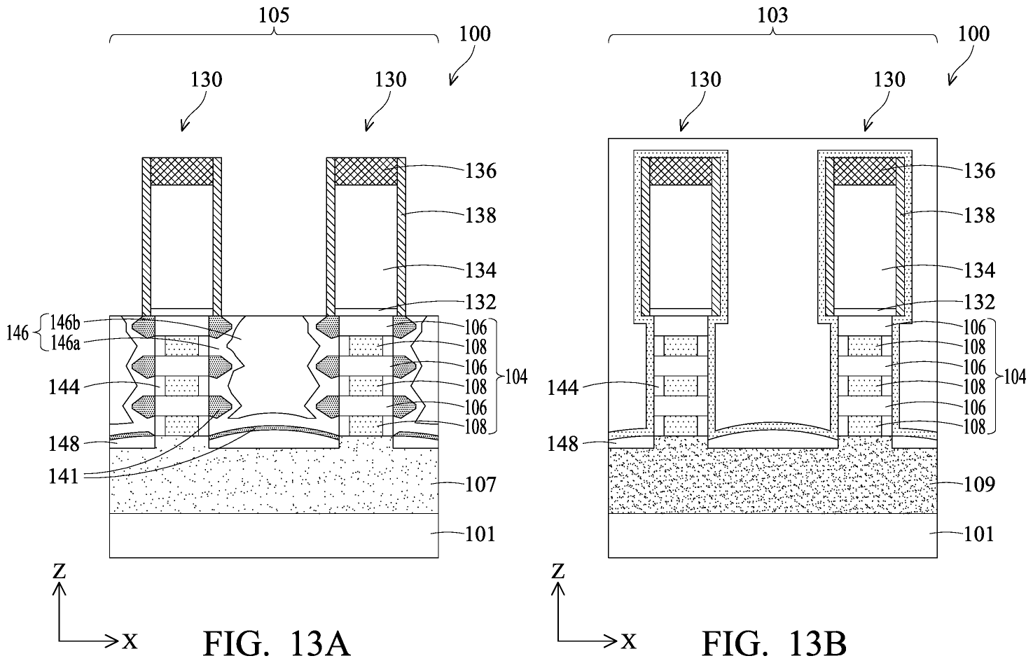

The blocking structure 141 serves as an etch stop layer to prevent etchant chemicals (used during subsequent removal of the second semiconductor layers 108) from leaking through the interface 135 (FIG. 12A-1) and into the S/D features 146. If the interface 135 is not blocked, the etch process to remove the second semiconductor layers 108 may also remove subsequently formed S/D features 146 (FIG. 13A), resulting in damaged S/D features 146. In some cases, the S/D features 146 may even be removed entirely by the etch process. The use of the blocking structure 141 ensures the interface 135 is blocked, which in turn minimizes the damage to the S/D features 146 during removal of the second semiconductor layers 108. As a result, the integrality of the S/D features 146 is preserved.

The blocking structure 141 may grow both vertically and horizontally to form facets, which may correspond to crystal planes of the material of the first semiconductor layers 106. Due to different growth rates on different surface planes, facets can be formed. For example, during the growth of the blocking structure 141, the growth rate on (111) planes of the first semiconductor layer 106 (e.g., silicon) may be lower than the growth rate on other planes, such as (110) and (100) planes of the first semiconductor layer 106. Therefore, facets are formed as a result of difference in growth rates of the different planes. The facet of the blocking structure 141 may include a plane from the family of {111} planes, the family of {100} planes, the family of {311} planes, the family of {911} planes.

In one embodiment, the blocking structure 141 may have a rhombus-like shape. In some embodiments, the blocking structure 141 may have rounded-like surface. FIG. 12A-1 illustrates an enlarged view of a portion of the semiconductor device structure 100 of FIG. 12A in accordance with some embodiments. As can be seen in FIG. 12A-1, the blocking structure 141 is in contact with the sidewall 106s of the first semiconductor layer 106, the sacrificial gate dielectric layer 132, and the gate spacer 138. Particularly, the blocking structure 141 extends across and covers the interface 135 defined by the gate spacer 138 and the sacrificial gate dielectric layer 132 (or the sacrificial gate electrode layer 134).

In some embodiments, the blocking structure 141 is formed of a doped semiconductor or doped semiconductor compound, such as a doped silicon, a doped germanium, a doped silicon germanium, or the like. In various embodiments, the dopant may be chosen from a group III element, such as boron. Therefore, the blocking structure 141 can include or be a boron-doped semiconductor material or a chemical compound involving boron and a semiconductor material. For example, the blocking structure 141 may be a boron-doped silicon (Si:B), a compound of boron and silicon, such as silicon triboride (SiB₃), silicon hexaboride (SiB₆), or the like, a boron-doped germanium (Ge:B), or a boron-doped silicon germanium (SiGe:B). In some embodiments, the blocking structure 141 is a boron-rich layer having a concentration of boron in a range of about 1 at. % to about 20 at. %. If the boron concentration is lower than about 1 at. %, the blocking structure 141 may not block the etchant leakage through the interface 135 during the subsequent replacement gate process. On the other hand, if the boron concentration is greater than about 20 at. %, the manufacturing cost is increased without obvious additional advantages for blocking etchant leakage. In some embodiments, which may be combined with any one or more embodiments of this disclosure, the blocking structure 141 has a constant concentration of germanium throughout the body of the blocking structure 141. In some embodiments, the germanium in the blocking structure 141 has a concentration gradually changing along the thickness of the blocking structure 141. For example, the blocking structure 141 may have a gradually increased concentration of germanium along the X-direction. Alternatively, the blocking structure 141 may have a gradually decreased concentration of germanium along the X-direction.

In some embodiments, the blocking structure 141 may have a dopant concentration in a range from about 5E20 atoms/cm³ to about 1E22 atoms/cm³. The dopants of boron, for example, may be incorporated into the blocking structure 141 during the growth of the blocking structure 141 by an EPI process or after the formation of the blocking structure 141 by an implantation process. In some embodiments, the blocking structure 141 may be a strained or relaxed structure. The blocking structure 141 may have a thickness D7 in a range of about 0.5 nm to about 10 nm. It has been observed that the blocking structure 141 formed of a highly doped semiconductor (e.g., Si:B) can effectively block the leakage through the interface 135. The blocking structure 141 can also retard etchant chemicals used to remove the second semiconductor layers 108 during the formation of nanostructure channels in a multi-gate device. As a result, the integrality of the subsequent S/D feature 146 is protected. High boron-doped blocking structure 141 also helps reduce resistivity for the S/D features 146 (P-type EPI). In addition, the use of boron-doped semiconductor as the blocking structure 141 may be advantageous because the boron dopants may alter crystal orientation of the underlying materials (e.g., first semiconductor layers 106 and the wells 107, 109 of the substrate 101) to promote facet formation of the blocking structure 141 and therefore, the growth of the subsequent epitaxial S/D features 146 on the facetted blocking structure 141.

Depending on the material of the blocking structure 141 to be formed, the exposed surfaces of the semiconductor device structure 100 may be exposed to a silicon-containing precursor(s), a germanium-containing precursor(s), a boron-containing precursor(s), an etching gas, and a diluent/carrier gas during the formation of the blocking structure 141. In cases where the blocking structure 141 includes boron-doped silicon germanium (SiGe:B), the blocking structure 141 may be formed by heating the semiconductor device structure 100 to a temperature of about 300 degrees Celsius to about 800 degrees Celsius, and exposing the first semiconductor layers 106 (and the wells 107, 109 of the substrate 101) to a precursor including at least a silicon-containing precursor, a germanium-containing precursor, and a boron-containing precursor. Suitable silicon-containing precursor may include, but is not limited to, silane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. Suitable germanium-containing precursor may include, but is not limited to, germane (GeH₄), digermane (Ge₂H₆), trigermane (Ge₃H₈), or germylsilane (GeH₆Si) or the like. Suitable gases for the boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. In cases etching gas(es) is used (e.g., in cyclic deposition etch (CDE) epitaxy process or selective etch growth (SEG) process), the deposition process may use one or more etching gases. Suitable etching gases may include, but are not limited to, hydrogen chloride (HCl), a chlorine gas (Cl₂), or the like. A diluent/purge gas, such as hydrogen (H₂), nitrogen (N₂), and/or argon (Ar), may be used along with the precursors for the blocking structure 141. In one embodiment, the blocking structure 141 is formed using precursors comprising SiH₄ and DCS, and B₂H₆. In another embodiment, the blocking structure 141 is formed using precursors comprising DCS, GeH₄, and B₂H6. In yet another embodiment, the blocking structure 141 is formed using precursors comprising DCS, GeH₄, and BCl₃. The formation of the blocking structure 141 may be performed in an epitaxial or CVD based reaction chamber.

In some embodiments, the blocking structure 141 is boron-doped silicon (Si:B) deposited by a CDE epitaxy process. The CDE epitaxy process may be performed in a process chamber at a temperature in a range between about 300° C. and 800° C., under a pressure in a range between about 1 Torr and 760 Torr, and performed for a time duration in a range between about 20 seconds and 300 seconds, by exposing the semiconductor device structure 100 to a gas mixture comprising one or more silicon-containing precursors (e.g., SiCl₂H₂, SiH₄, etc.), a p-type dopant gas (e.g., B₂H₆), and a carrier gas (e.g., Ar, H₂, etc.) for a first period of time to form a first portion of the blocking structure 141, followed by a selective etch where the first portion of the blocking structure 141 is exposed to etchants (e.g., HCl, etc.) for a second period of time to selectively remove amorphous or polycrystalline portions of the blocking structure 141 while leaving crystalline portions of the blocking structure 141 intact. The process chamber may be flowed with a purge gas (e.g., N₂) between the epitaxial growth and the selective etch. The silicon-containing precursor(s) may be provided at a flow rate in a range between about 10 sccm and about 500 sccm, the dopant gas may be provided at a flow rate in a range between about 10 sccm and about 500 sccm, the carrier gas may be provided at a flow rate in a range between about 0 sccm and about 50000 sccm, and the purge gas may be provided at a flow rate in a range between about 0 sccm and about 50000 sccm. The epitaxial growth and selective etch of the CDE epitaxy process are repeated until a desired thickness the blocking structure 141 and above-mentioned dopant concentration (e.g., first dopant concentration) are achieved.

Once the predetermined volume of the blocking structure 141 is reached, the flow of the boron-containing precursor(s) may be terminated and group IV or group V precursor(s) are introduced into the process chamber along with the silicon-containing precursor(S) to form the S/D features 146. Therefore, the blocking structure 141 is formed of a material that is chemically different from that of the subsequent S/D features 146. The dopants in the S/D features 146 may be added during the formation of the S/D features 146, or after the formation of the S/D features 146 by an implantation process.

In FIGS. 13A and 13B, after formation of the blocking structure 141, S/D features 146 are formed in the S/D regions between the neighboring sacrificial gate structures 130 at the second device region 105. The S/D epitaxial features 146 may include a first epitaxial layer 146a and a second epitaxial layer 146b formed on the first epitaxial layer 146a. The first and second epitaxial layers 146a. 146b may be formed by any suitable process, such as cyclic deposition etch (CDE) epitaxy process, selective etch growth (SEG) process, ALD, molecular beam epitaxy (MBE), or any combination thereof. The S/D features 146 may be the S/D regions. For example, one of a pair of S/D features 146 located on one side of the sacrificial gate structures 130 may be a source region, and the other of the pair of S/D features 146 located on the other side of the sacrificial gate structures 130 may be a drain region. A pair of S/D features 146 includes a source feature 146 and a drain feature 146 connected by the nanostructure channels (i.e., the first semiconductor layers 106). A source and a drain are interchangeably used in this disclosure.

The first epitaxial layer 146a is conformally formed on the blocking structure 141 and the dielectric spacers 144. In some embodiments, the first epitaxial layer 146a includes the same material as the epitaxial layer 148 with a higher dopant concentration. In some embodiments, the first epitaxial layer 146a is formed of silicon germanium, and the Ge concentration is in a range between about 25% and 40%. Depending on the conductivity type of the device to be formed at the second device region 105, the first epitaxial layer 146a may have n-type dopants or p-type dopants. The first epitaxial layer 146a serves as a leakage barrier layer to prevent possible diffusion of subsequent backside metallic elements into the gate area. The first epitaxial layer 146a may also function as lattice transitional layer between the blocking structure 141 and the second epitaxial layer 146b.

In some embodiments, the first epitaxial layer 146a is a dopant-rich layer. In such cases, the first epitaxial layer 146a may contain P-type dopants and the dopant concentration may be in a range between about 1E20 atoms/cm³ and about 8E20 atoms/cm³. In some embodiments, the first epitaxial layer 146a contains phosphorus and the dopant concentration is in a range between about 1E20 atoms/cm³ and about 5E20 atoms/cm³. The dopants may be implanted using the sacrificial gate structures 130 and the gate spacers 138 as masks. The first epitaxial layer 146a may have a thickness along the Z-direction in a range between about 3 nm and about 20 nm. If the thickness of the first epitaxial layer 146a is below 3 nm, the first epitaxial layer 146a may not be thick enough to function as the leakage barrier layer nor the lattice transitional layer between the blocking structure 141 and the second epitaxial layer 146b to be formed. If the thickness of the first epitaxial layer 146a is greater than 20 nm, the manufacturing cost is increased without obvious additional advantages for crystalline structural transition.

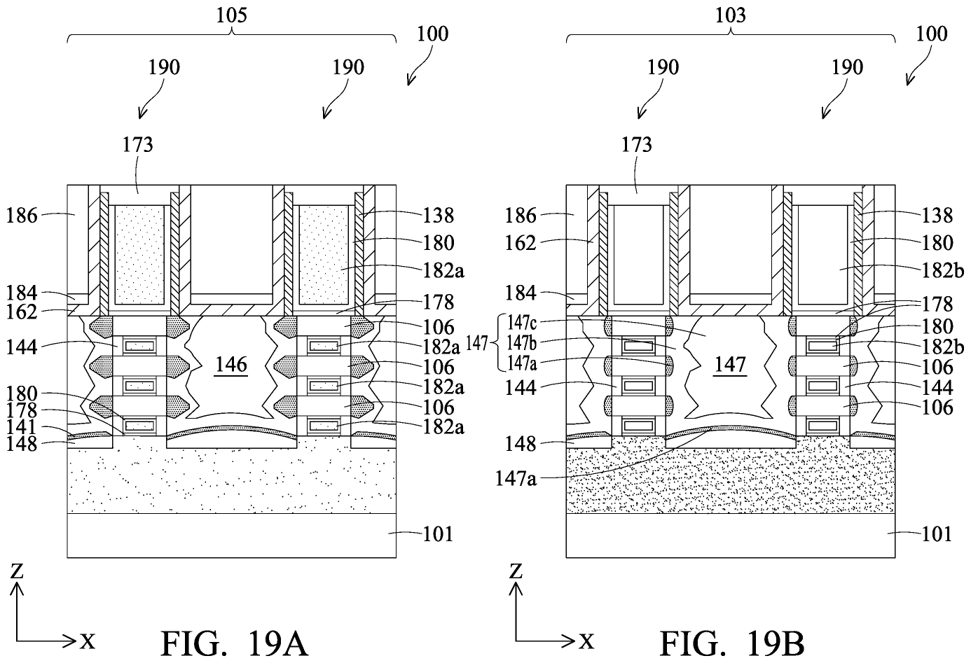

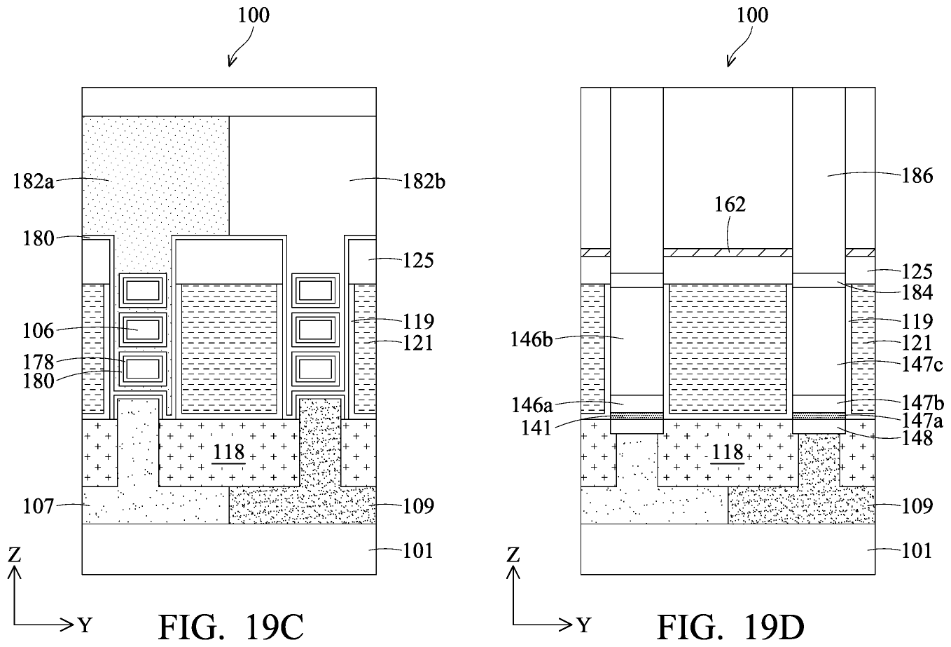

The second epitaxial layer 146b is formed on the first epitaxial layer 146a and having at least sidewalls surrounded by the first epitaxial layer 146a. In some embodiments, at least three surfaces of the second epitaxial layer 146b are in contact with the first epitaxial layer 146a. The second epitaxial layer 146b forms a major portion of the epitaxial S/D feature 146. In cases where the second device region 105 is used for forming P-type devices, the second epitaxial layer 146b may include Si, SiGe, or Ge. In some embodiments, the second epitaxial layer 146b is formed of silicon germanium, and the Ge concentration is in a range between about 50% and 60%. Depending on the conductivity type of the device to be formed at the second device region 105, the second epitaxial layer 146b may have n-type dopants or p-type dopants. In either case, the second epitaxial layer 146b has a dopant concentration higher than the dopant concentration of the first epitaxial layer 146a. The higher dopant concentration of the second epitaxial layer 146b can reduce contact resistance for the epitaxial S/D features 146 and provide better conductivity with the subsequently formed source/drain metal contact (e.g., side source/drain contact 186 in FIGS. 19A and 19B). In some embodiments, the second epitaxial layer 146b contains boron and the dopant concentration is in a range between about 8E20 atoms/cm³ and about 3E21 atoms/cm³. In some embodiments, the second epitaxial layer 146b contains phosphorus and the dopant concentration is in a range between about 5E20 atoms/cm³ and about 4E21 atoms/cm³. Likewise, the dopants for the second epitaxial layer 146b may be implanted using the sacrificial gate structures 130 and the gate spacers 138 as masks. Alternatively, the dopants for the first and second epitaxial layers 146a, 146b may be implanted after formation of the first and second epitaxial layers 146a, 146b.

In FIGS. 14A-14D, the S/D features 146 and the sacrificial gate structures 130 at the second device region 105 are protected with a hard mask layer 113 and a photoresist layer 115, such as the hard mask layer 137 and the photoresist layer 139 discussed above with respect to FIGS. 11A and 11B. Once the second device region 105 has been protected, the hard mask layer 137 and the photoresist layer 139 at the first device region 103 are removed (through, e.g., ashing) to expose the sacrificial gate structure 130, the first semiconductor layers 106, the inner spacers 144, and the epitaxial layer 148. Then, S/D features 147 are formed in the S/D regions between the neighboring sacrificial gate structures 130 at the first device region 103.

The S/D features 147 may include a first epitaxial layer 147a, a second epitaxial layer 147b, and a third epitaxial layer 147c. The first, second, and third epitaxial layers 147a, 147b, 147c may be formed by any suitable process, such as cyclic deposition etch (CDE) epitaxy process, selective etch growth (SEG) process, ALD, molecular beam epitaxy (MBE), or any combination thereof. The first epitaxial layer 147a may include a semiconductor material, such as Si, SiP, SiC, SiAs, and SiCP. The first epitaxial layer 147a may have n-type dopants (e.g., phosphorus (P) or arsenic (As)). The first epitaxial layer 147a may have a first dopant concentration lower than a dopant concentration of the second epitaxial layer 147b. The lower dopant concentration of the first epitaxial layer 147a avoids dopant diffusion into the channel regions (e.g., the first semiconductor layers 106). The first epitaxial layer 147a may also serve as a blocking structure to prevent etchant chemicals (used during subsequent removal of the second semiconductor layers 108) from leaking into the S/D features 147. In some embodiments, the first epitaxial layer 147a may be an undoped silicon layer. The first epitaxial layer 147a on the first semiconductor layers 106 may have a curved or rounded surface.

The second epitaxial layer 147b is formed on the first epitaxial layer 147a. In some embodiments, the second epitaxial layer 147b is a semiconductor material, such as Si, SiP, SiC. SiAs, and SiCP. Likewise, the second epitaxial layer 147b may have n-type dopants. The second epitaxial layer 147b may have a second dopant concentration lower than a dopant concentration of the third epitaxial layer 147c. In some embodiments, the second dopant concentration is in a range between about 15E19 atoms/cm³ and about 5E20 atoms/cm³. Like the first epitaxial layer 146a, the second epitaxial layer 147b may have a thickness along the Z-direction in a range between about 3 nm and about 15 nm.

The third epitaxial layer 147c is formed on the second epitaxial layer 147b and having at least sidewalls surrounded by the second epitaxial layer 147b. The third epitaxial layer 147c forms a major portion of the epitaxial S/D feature 147. Similarly, the third epitaxial layer 147c may be a semiconductor material, such as Si, SiP, SiC, SiAs, and SiCP. The third epitaxial layer 147c may have n-type dopants. The third epitaxial layer 147c may have a third dopant concentration higher than the second dopant concentration of the second epitaxial layer 147b. The higher dopant concentration of the third epitaxial layer 147c can reduce contact resistance for the epitaxial S/D features 147 and provide better conductivity with the subsequently formed source/drain metal contact (e.g., S/D contacts 186 in FIGS. 19A and 19B). In some embodiments, the third dopant concentration is in a range between about 1E20 atoms/cm³ and about 5E21 atoms/cm³.

FIGS. 14A-1 and 14B-1 are enlarged views of a portion of the semiconductor device structure 100, showing respectively the blocking structure 141 and the first epitaxial layer 147a in accordance with some embodiments. As can be seen in FIG. 14A-1, the blocking structure 141 is a facetted structure having a rhombus-like shape. The facetted structure is formed with at least facets 141a, 141b. The facets 141a-b of the facetted structure provide increased surface area to promote epitaxial growth of the S/D features 146a, 146b (146). Particularly, the blocking structure 141 extends over and covers the interface 135 defined by the gate spacer 138 and the sacrificial gate dielectric layer 132 (or the sacrificial gate electrode layer 134). The embodiment shown in FIG. 14B-1 is similar to that of FIG. 14A-1 except the first epitaxial layer 147a on the first semiconductor layers 106 may not have facetted surface but a curved or rounded profile. The epitaxial layer 147a is in contact with the first semiconductor layer 106, the sacrificial gate dielectric layer 132, and the gate spacer 138. The epitaxial layer 147a may extend to cover the interface 135.

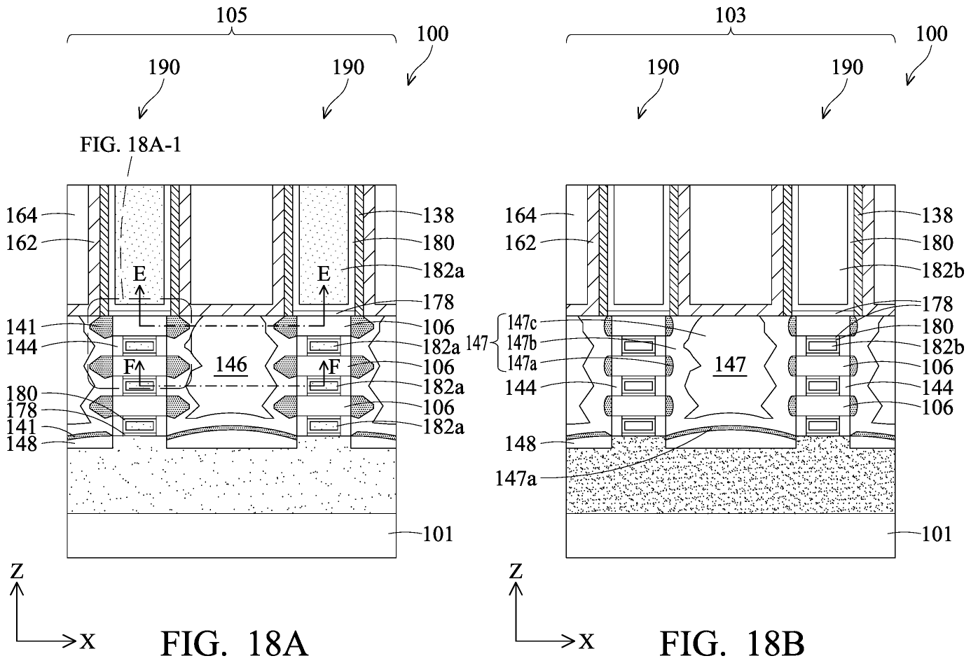

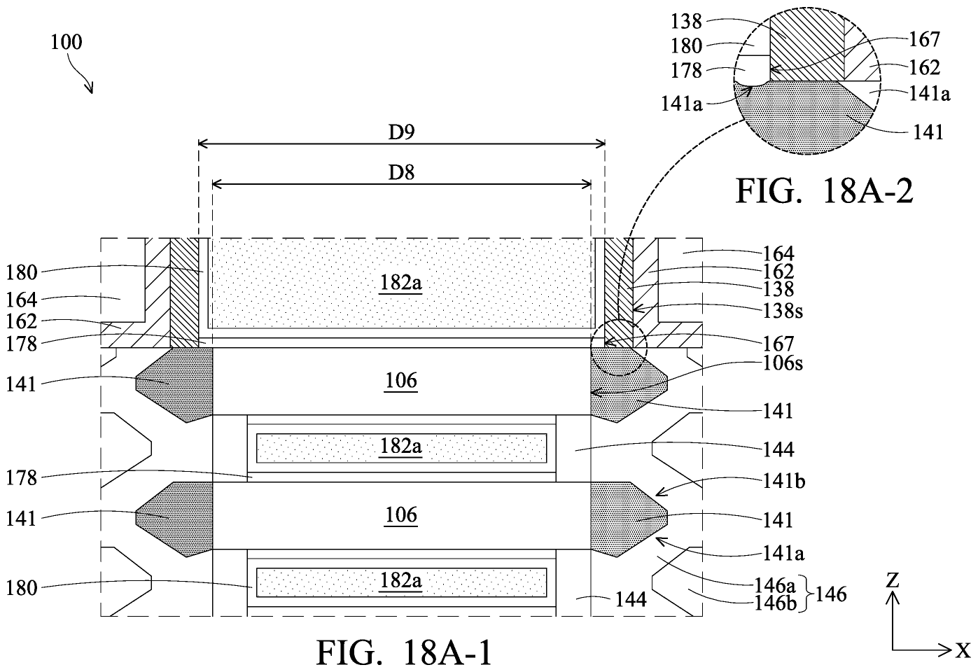

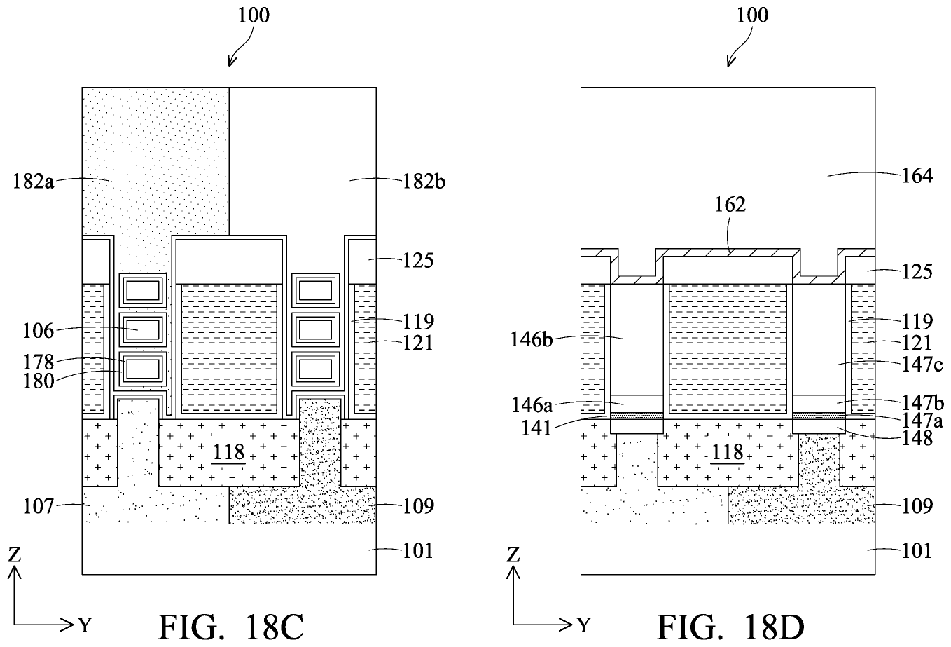

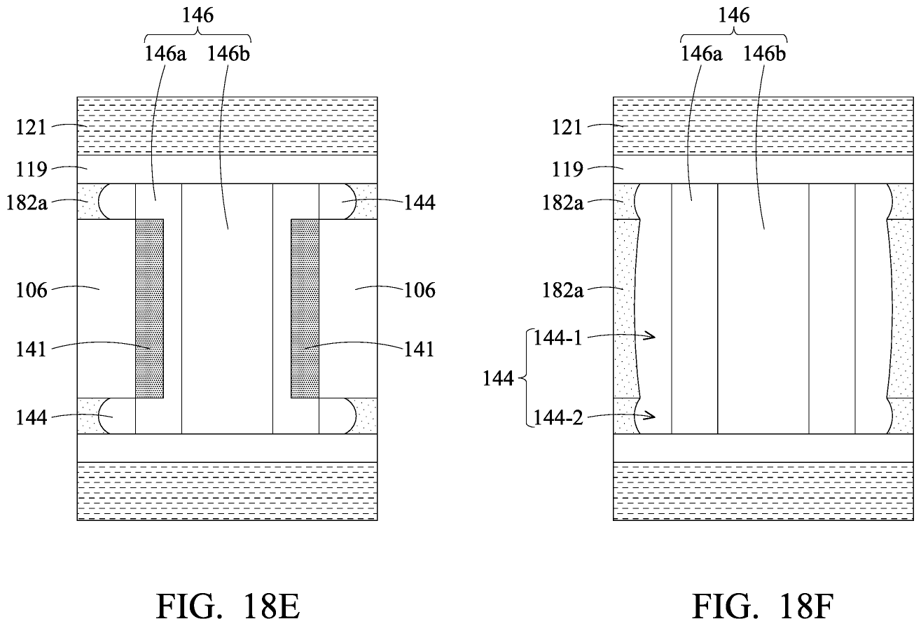

FIG. 14E illustrates a top view of a portion of the semiconductor device structure 100 taken along cross-section E-E of FIG. 14A, in accordance with some embodiments. As can be seen in FIG. 14E, the blocking structure 141 is grown from the first semiconductor layer 106. The blocking structure 141 may have at least three surfaces in contact with the first epitaxial layer 146a of the S/D feature 146. A first side of the inner spacer 144 is substantially flat and disposed against the S/D feature 146 (e.g., first epitaxial layer 146a), and a second side of the inner spacer 144 is curved (has a substantially convex shape, for example) and disposed against the cladding layer 117. It should be noted that the cladding layer 117 will subsequently be removed and replaced with materials from a replacement gate structure 190 (FIG. 18B), such as an interfacial layer (IL) 178, a gate dielectric layer 180, and/or a gate electrode layer 182b. Therefore, the inner spacer 144 may be in contact with the IL 178 (e.g., FIG. 18E), the gate dielectric layer 180 (e.g., FIG. 18E), and/or the gate electrode layer 182a (e.g., FIG. 18E) in some embodiments.

FIG. 14F illustrates a top view of a portion of the semiconductor device structure 100 taken along cross-section F-F of FIG. 14B, in accordance with some embodiments. In this view, portions of the second semiconductor layers 108 and the cladding layer 117 are recessed since they may include the same material (e.g., SiGe). The removal of the portions of the second semiconductor layers 108 and the cladding layer 117 creates room for the inner spacer 144. In one embodiment, the inner spacer 144 may include a first portion 144-1 disposed between and in contact with the second semiconductor layer 108 and the S/D feature 146 (e.g., first epitaxial layer 146a), and at least a second portion 144-2 disposed between and in contact with the cladding layer 117 and the S/D feature 146 (e.g., first epitaxial layer 146a). A first side of the first and second portions 144-1, 144-2 is substantially flat and disposed against the S/D feature 146, and a second side of the first and second portions 144-1, 144-2 is curved (has a substantially convex shape, for example). Likewise, the cladding layer 117 and the second semiconductor layer 108 will subsequently be removed and replaced with materials from the replacement gate structure 190, such as the IL 178, the gate dielectric layer 180, and/or the gate electrode layer 182b. Therefore, the first portion 144-1 and the second portion 144-2 may be in contact with the IL 178 (e.g., FIG. 18F), the gate dielectric layer 180 (e.g., FIG. 18F), and/or the gate electrode layer 182b in some embodiments (e.g., FIG. 18F).

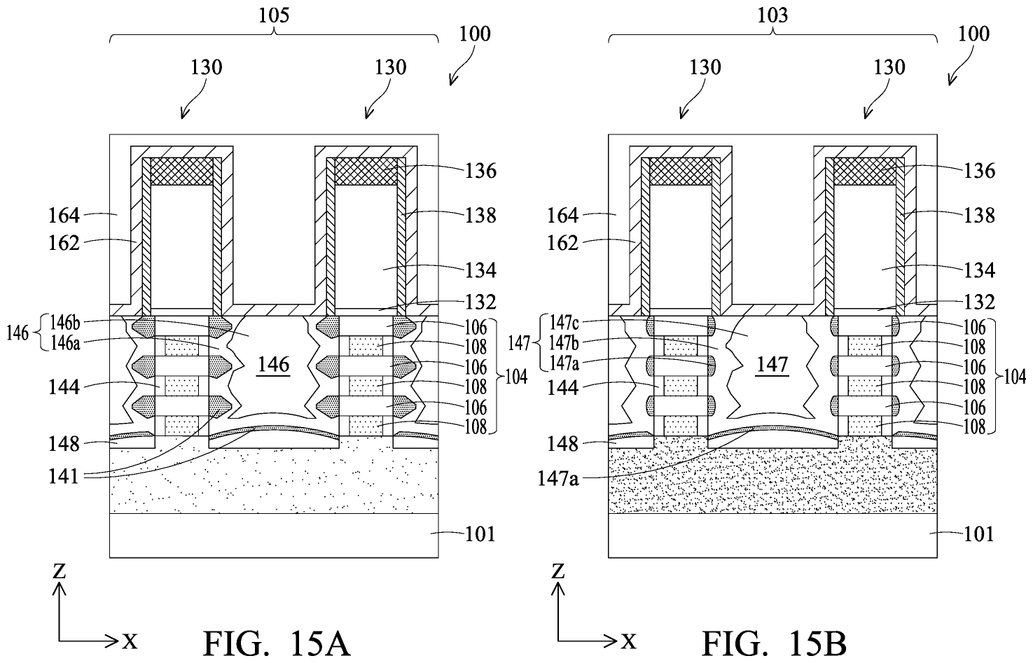

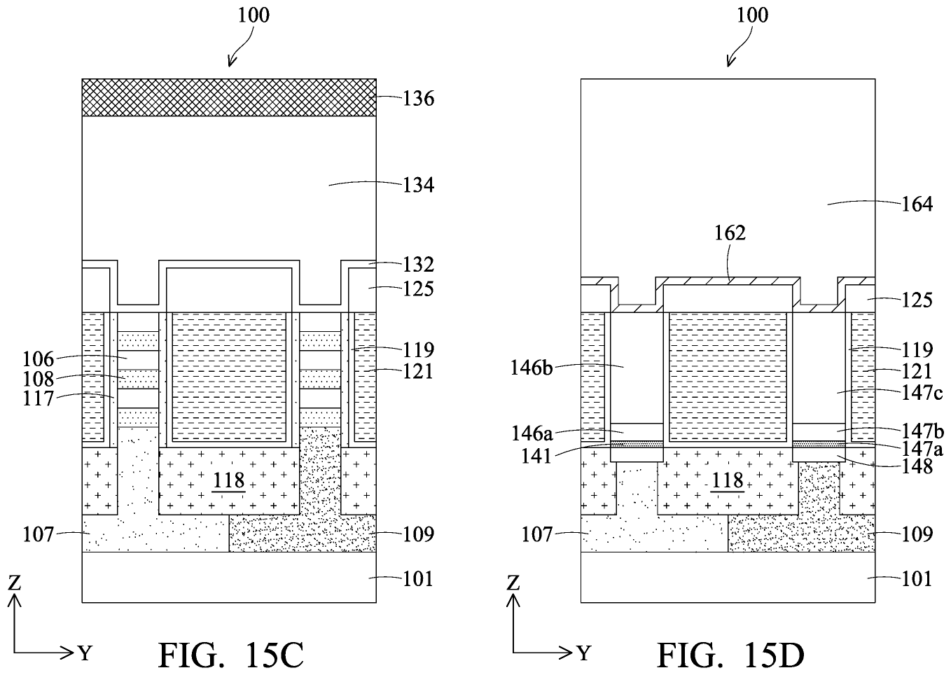

In FIGS. 15A-15D, after formation of the S/D features 146, 147, a contact etch stop layer (CESL) 162 is conformally formed on the exposed surfaces of the semiconductor device structure 100. The CESL 162 covers the S/D features 146, 147, the gate spacers 138, and the dielectric material 125 at the first and second device regions 103, 105. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include oxide formed with tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C. and/or H. The ILD layer 164 may be deposited by a PECVD process or other suitable deposition technique.

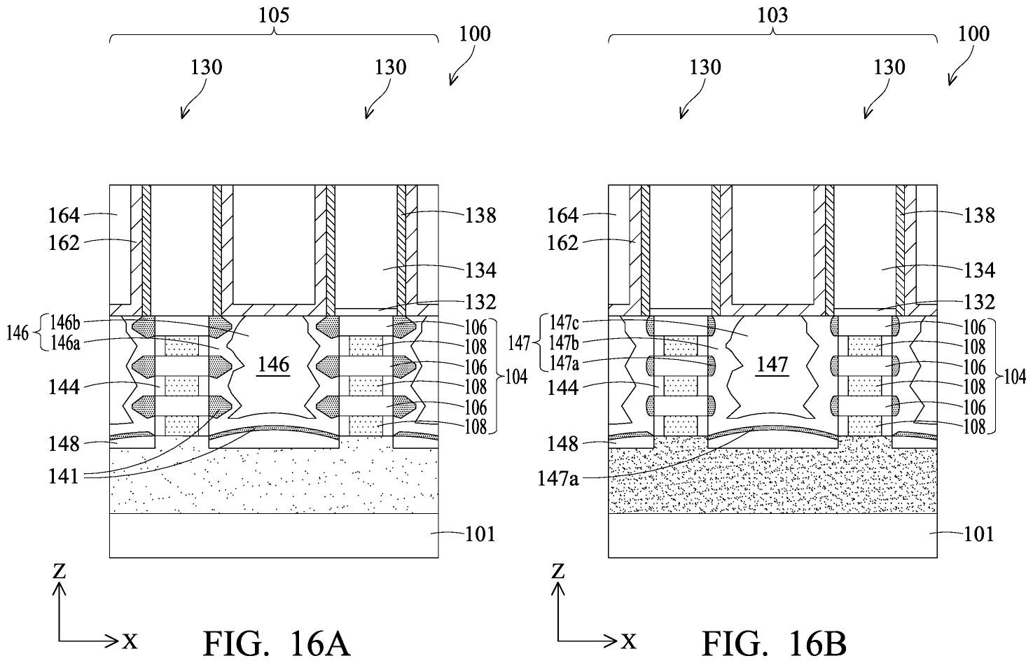

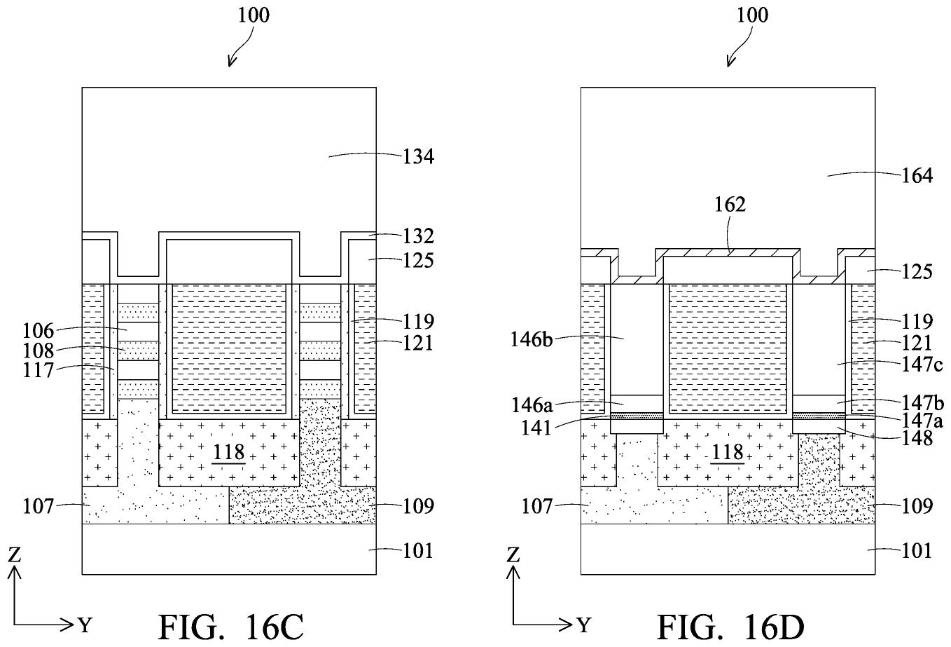

In FIGS. 16A-16D, once the ILD layer 164 has been formed, a planarization operation, such as CMP, is performed on the semiconductor device structure 100 to remove portions of the ILD layer 164, the CESL 162, and the mask layer 136 until the sacrificial gate electrode layer 134 is exposed.

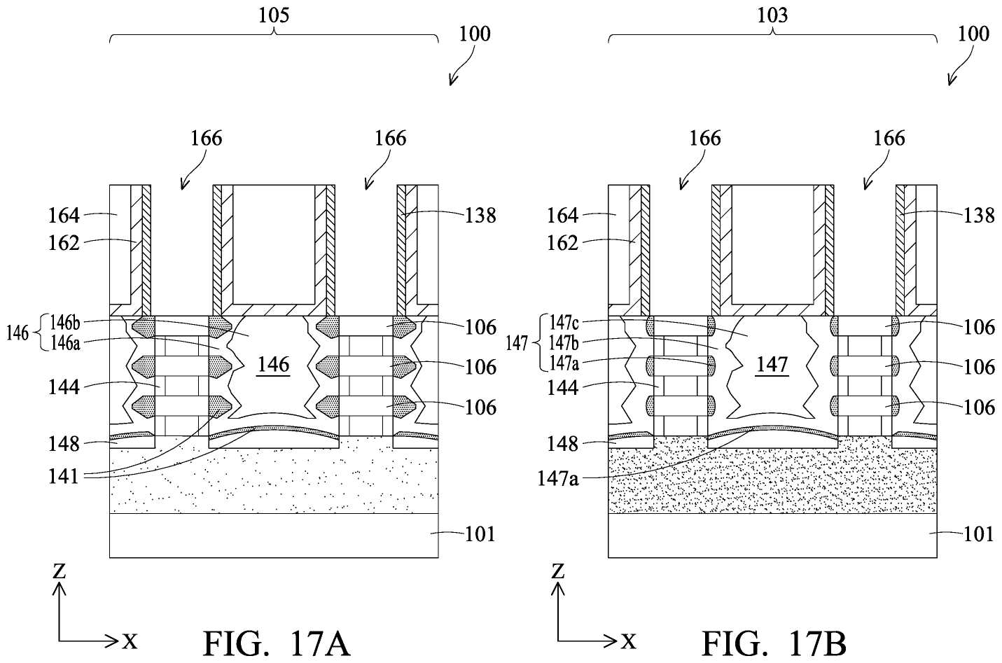

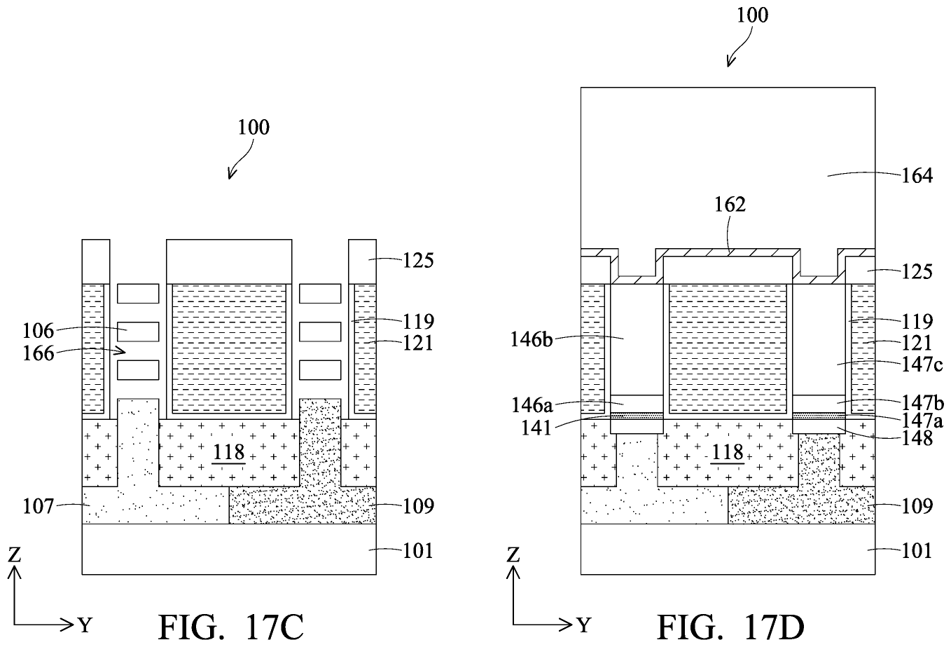

In FIGS. 17A-17D, the sacrificial gate structure 130, the cladding layer 117, and the second semiconductor layers 108 are removed from the semiconductor device structure 100 at the first and second device regions 103, 105. The removal of the sacrificial gate structure 130 and the semiconductor layers 108 forms an opening 166 between gate spacers 138 and between first semiconductor layers 106. The ILD layer 164 protects the S/D epitaxial features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 125, the ILD layer 164, and the CESL 162. In some embodiments, the gate spacers 138 may be recessed by the etchant used to remove the sacrificial gate electrode layer 134 and/or the sacrificial gate dielectric layer 132.

After the removal of the sacrificial gate structure 130, the cladding layers 117 and the second semiconductor layers 108 are exposed. The removal of the cladding layers 117 and the second semiconductor layers 108 exposes the first semiconductor layers 106. The blocking structure 141 (and the first epitaxial layer 147a) minimizes or avoids the damage to the S/D features 146, 147 by blocking the etchant from passing through the interface 135 (defined by the sacrificial gate dielectric 132 and the gate spacer 138, see FIG. 14A-1) during removal of the cladding layers 117 and the second semiconductor layers 108. Therefore, the integrality of the S/D features 146, 147 is preserved. The removal process may be any suitable etch processes, such as dry etch, wet etch, or a combination thereof. The etch process may use an etchant that selectively removes the cladding layers 117 and the second semiconductor layers 108 without substantially removing the gate spacers 138, the ILD layer 164, the CESL 162, the dielectric material 125, the first semiconductor layers 106, the blocking structure 141, and the first epitaxial layer 147a. In one embodiment where the first semiconductor layers 106 is Si and the second semiconductor layers 108 is SiGe, the etchant may be an ammonium hydroxide (NH₄OH) and H₂O₂ solution or any suitable etchant. Upon removal of the sacrificial gate structure 130 and the second semiconductor layers 108, a portion of the first semiconductor layers 106, the blocking structure 141, and the first epitaxial layer 147a are exposed in the opening 166.

In FIGS. 18A-18D, replacement gate structures 190 are formed in the region provided by removal of the cladding layers 117 and the second semiconductor layers 108 at the first and second device regions 103, 105. The replacement gate structures 190 each includes an interfacial layer (IL) 178, a gate dielectric layer 180, and a gate electrode layer 182a/182b. The interfacial layer (IL) 178 is formed to surround exposed surfaces of the first semiconductor layers 106. The IL 178 may also form on the exposed wells 107, 109 of the substrate 101. The IL 178 may include or be made of an oxygen-containing material or a silicon-containing material, such as silicon oxide, silicon oxynitride, oxynitride, hafnium silicate, etc. In one embodiment, the IL 178 is silicon oxide. The IL 178 may be formed by CVD, ALD, a clean process, or any suitable process. Next, the gate dielectric layer 180 is formed on the exposed surfaces of the semiconductor device structure 100. Portions of the IL 178 and optionally the gate dielectric layer 180 are in contact with the blocking structure 141. In some embodiments, the gate dielectric layer 180 is formed to wrap around and in contact with the IL 178. The gate dielectric layer 180 also forms on and in contact with the liner 119 and the dielectric material 125 (FIGS. 18C and 18D). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (Al₂O₃), aluminum silicon oxide (AlSiO), zirconium oxide (ZrO), titanium oxide (TiO), tantalum oxide (Ta₂O₅), yttrium oxide (Y₂O₃), silicon oxynitride (SiON), oxide with nitrogen doped dielectrics combined with metal content high-k dielectric (having a k value >13), or other suitable dielectrics having a k value ≥9. The gate dielectric layer 180 may be a conformal layer formed by a conformal process, such as an ALD process or a CVD process. The gate dielectric layer 180 may have a thickness in a range of about 0.5 nm to about 3 nm.

After formation of the IL 178 and the gate dielectric layer 180, the gate electrode layer 182a/182b is formed over the gate dielectric layer 180. The gate electrode layer 182a may be formed to fill the openings 166 (FIGS. 17A and 17B) and fully surround a portion of each of the first semiconductor layers 106 at the second device region 105. The gate electrode layer 182b may be formed to fill the openings 166 and fully surround a portion of each of the first semiconductor layers 106 at the first device region 103. In some embodiments, the gate electrode layers 182a, 182b may be formed using multiple layers, each layer deposited sequentially adjacent to each other using a highly conformal deposition process such as ALD. Other deposition technique such as PVD, CVD, or electro-plating may also be used. While not shown, the gate electrode layer 182a may include a capping layer, a barrier layer, an n-metal work function layer, a p-metal work function layer, and a fill material. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The n-metal work function layer may be formed from a metallic material such as W, Cu, AlCu, TiAlC, TiAlN, Ti, TiN, Ta, TaN, Co, Ni, Ag, Al, TaAl, TaAlC, TaC, TaCN, TaSiN, Mn, Zr, other suitable N-type work function materials, or combinations thereof. The p-metal work function layer may be formed from a metallic material such as W, Al, Co, TiN, Ti, TiAlN, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Once the n-metal work function layer and the p-metal work function layer are formed, the fill material is deposited to fill a remainder of the opening 166. The fill material may be a material such as W, Al, Cu, AlCu, W, Ti, TiAlN, TaC, TaCN, TaSIN, Mn, Zr, TiN, Ta, TaN, Co, Ni, combinations of these, or the like.

Similarly, the gate electrode layer 182b may be formed using multiple layers and materials similar to the gate electrode layer 182a discussed above. In some embodiments, one or more of the layers within the gate electrode layer 182a and the gate electrode layer 182b may be formed during a same series of steps. For example, the capping layers and the barrier layers in both of the gate electrode layer 182a and the gate electrode layer 182b may be formed simultaneously, while other layers such as the n-metal work function layer and the p-metal work function layer may be formed and/or patterned independently of each other. Any suitable combination of depositions and removals may be utilized to form the gate electrode layer 182a and the gate electrode layer 182b.

Once the openings 166 have been filled, the materials of the gate electrode layer 182a and the gate electrode layer 182b may be planarized by a planarization process (e.g., CMP) to remove any material that is outside of the openings left behind by the removal of the sacrificial gate electrode layer 134.

FIG. 18A-1 illustrates an enlarged view of a portion of the semiconductor device structure 100 of FIG. 18A in accordance with some embodiments. The first semiconductor layers 106 defined between two adjacent blocking structures 141 may have a length D8. The IL 178 is disposed between and in contact with the gate dielectric layer 180 and the first semiconductor layer 106. A portion of the IL 178 is further in contact with the blocking structure 141. The IL 178 above the topmost first semiconductor layer 106 may have a length D9 greater than the length D8. The first semiconductor layer 106 is surrounded by the IL 178. The gate dielectric layer 180 is disposed to surround the IL 178. The gate electrode layer 182a is disposed on the IL 178 and arranged to surround the first semiconductor layer 106. The blocking structure 141 is in contact with the topmost first semiconductor layer 106, the IL 178, the gate spacer 138, and the first epitaxial layer 146a. In some embodiments, the blocking structure 141 is further in contact with the CESL 162 (FIG. 18A-2). Particularly, the blocking structure 141 extends a distance along the X direction to cover an interface 167 defined by the IL 178 and the gate spacer 138. FIG. 18A-2 illustrates an enlarged view of a portion of the semiconductor device structure 100 of FIG. 18A-1 in accordance with some embodiments. In this embodiment, a portion of the blocking structure 141 is removed during the removal of the sacrificial gate structure 130, resulting in a recess 141a adjacent the interface 167. The bottom of the IL 178 in contact with the topmost first semiconductor layer 106 may have a curved profile due to the recess 141a.

FIG. 18E illustrates a top view of a portion of the semiconductor device structure 100 taken along cross-section E-E of FIG. 18A, in accordance with some embodiments. The embodiment shown in FIG. 18E is substantially identical to the embodiment shown in FIG. 14E except that the cladding layer 117 has been replaced with the gate electrode layer 182a. FIG. 18F illustrates a top view of a portion of the semiconductor device structure 100 taken along cross-section F-F of FIG. 18B, in accordance with some embodiments. Likewise, the embodiment shown in FIG. 18F is substantially identical to the embodiment shown in FIG. 14F except that the second semiconductor layer 108 and the cladding layer 117 have been replaced with the gate electrode layer 182b.

In FIGS. 19A-19D, the gate electrode layer 182a, 182b may be subject to one or more metal gate etching back (MGEB) processes. The MGEB processes are performed so that the top surfaces of the gate electrode layer 182a, 182b and the gate dielectric layer 180 are recessed to a level below the top surface of the gate spacers 138. In some embodiments, the gate spacers 138 are also recessed to a level below the top surface of the ILD layer 164, as shown in FIGS. 19A and 19B. A self-aligned contact layer 173 is formed over the gate electrode layer 182a, 182b and the gate dielectric layer 180 between the gate spacers 138. The self-aligned contact layer 173 may be a dielectric material having an etch selectivity relative to the ILD layer 164. In some embodiments, the self-aligned contact layer 173 may be a dielectric material such as silicon nitride or a high-k dielectric layer. Once formed, the self-aligned contact layer 173 may be planarized using a planarization process such as a CMP.

After formation of the self-aligned contact layer 173, contact openings are formed through the ILD layer 164 and the CESL 162 to expose the epitaxial S/D feature 146, 147. A silicide layer 184 is then formed on the S/D epitaxial feature 146, 147, and a S/D contact 186 is formed in the contact opening on the silicide layer 184. The contact 186 may include an electrically conductive material, such as Al, Cu, W, Co, Ti, Ta, Ru, TiN, TiAl, TiAlN, TaN, TaC, NiSi, CoSi, combinations of these, or the like. The silicidation may be performed by blanket deposition of an appropriate metal layer, followed by an annealing step which causes the metal to react with the underlying exposed silicon. Un-reacted metal is then removed, such as with a selective etch process. The contact 186 may be formed in the contact openings using sputtering, CVD, electroplating, electroless plating, or the like, to fill and/or overfill the contact openings. Any deposited material outside of the contact openings may be removed using a planarization process, such as a CMP.

The semiconductor device structure 100 may then undergo further complementary metal oxide semiconductor (CMOS) and/or back-end-of-line (BEOL) processes to form various features such as transistors, contacts/vias, interconnect metal layers, dielectric layers, passivation layers, etc.

Various embodiments or examples described herein offer multiple advantages over the state-of-art technology. According to embodiments of the present disclosure, wire release induced damages to S/D features of nanostructure channel FETs can be prevented by providing a blocking structure 141 to seal an interface 135 (FIG. 14A-1) defined by a sacrificial gate dielectric and a gate spacer prior to gate replacement process. The blocking structure 141 may be a highly doped semiconductor (e.g., Si:B) or compound material (e.g., SiGe:B). The blocking structure 141 can effectively block etchant chemicals used during nanostructure formation process from leaking to the S/D features through the interface 135. As a result, the integrality of the S/D features is preserved. The use of highly doped semiconductor in the blocking structure 141 also helps reduce resistivity in P-EPI.

An embodiment is a semiconductor device structure. The semiconductor device structure includes a first source/drain feature and a second source/drain feature, a plurality of semiconductor layers vertically stacked and disposed between the first and second source/drain features, a gate electrode layer surrounding a portion of each of the plurality of the semiconductor layers, and an interfacial layer (IL) disposed between the gate electrode layer and one of the plurality of the semiconductor layers, wherein a topmost semiconductor layer of the plurality of the semiconductor layers has a first length, and the IL has a second length greater than the first length.

Another embodiment is a semiconductor device structure. The semiconductor device structure includes a plurality of semiconductor layers vertically and parallelly stacked, a gate electrode layer fully surrounding a portion of each of the plurality of the semiconductor layers, an interfacial layer (IL) disposed between the gate electrode layer and a topmost semiconductor layer of the plurality of the semiconductor layers, a gate spacer disposed adjacent the gate electrode layer and in contact with the IL, and a blocking structure in contact with a sidewall of each of the plurality of the semiconductor layers, wherein the blocking structure covers an interface defined by the IL and the gate spacer.

A further embodiment is a method for forming a semiconductor device structure. The method includes forming a fin structure from a stack of semiconductor layers comprising a plurality of first semiconductor layers and a plurality of second semiconductor layers alternatingly stacked, forming a sacrificial gate structure over a portion of the fin structure, wherein the sacrificial gate structure comprises a sacrificial gate dielectric and a sacrificial gate electrode layer. The method also includes forming a gate spacer on sidewalls of the sacrificial gate structure, removing portions of the fin structure not covered by the sacrificial gate structure, subjecting the first and second semiconductor layers to an etch process to form cavities at opposing ends of the second semiconductor layers, forming a dielectric spacer in the cavities, forming a blocking structure on opposing ends of the first semiconductor layers, wherein the blocking structure covers an interface defined by the sacrificial gate dielectric and the sacrificial gate electrode layer. The method also includes forming a source/drain feature on opposite sides of the sacrificial gate structure, wherein the source/drain feature is in contact with the blocking structure. The method further includes removing the sacrificial gate structure and the plurality of second semiconductor layers to expose portions of the plurality of first semiconductor layers and the blocking structure, and forming a gate electrode layer to surround the exposed portion of the plurality of first semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain feature and a second source/drain feature;
a plurality of semiconductor layers vertically stacked and disposed between the first and second source/drain features;
a gate electrode layer surrounding a portion of each of the plurality of the semiconductor layers; and
an interfacial layer (IL) disposed between the gate electrode layer and one of the plurality of the semiconductor layers,
wherein a topmost semiconductor layer of the plurality of the semiconductor layers has a first length, and the IL has a second length greater than the first length.

2. The semiconductor device structure of claim 1, further comprising:
a blocking structure in contact with a sidewall of each of the plurality of the semiconductor layers.

3. The semiconductor device structure of claim 2, further comprising:
a gate spacer in contact with the IL and the blocking structure.

4. The semiconductor device structure of claim 3, wherein a portion of the blocking structure is in contact with the first or second source/drain feature.

5. The semiconductor device structure of claim 3, wherein the blocking structure extends over an interface defined by IL and the gate spacer.

6. The semiconductor device structure of claim 2, wherein the blocking structure comprises a doped semiconductor or doped semiconductor compound.

7. The semiconductor device structure of claim 6, wherein the blocking structure is a boron-doped semiconductor material or a chemical compound involving boron and a semiconductor material.

8. The semiconductor device structure of claim 7, wherein the blocking structure has a dopant concentration in a range of about 1 at. % to about 20 at. %.

9. The semiconductor device structure of claim 6, wherein the blocking structure is boron-doped silicon germanium.

10. The semiconductor device structure of claim 9, wherein the blocking structure has a constant concentration of germanium throughout the thickness of the blocking structure.

11. The semiconductor device structure of claim 9, wherein the germanium in the blocking structure has a concentration gradually changing along the thickness of the blocking structure.

12. A semiconductor device structure, comprising:
a plurality of semiconductor layers vertically and parallelly stacked;
a gate electrode layer fully surrounding a portion of each of the plurality of the semiconductor layers;
an interfacial layer (IL) disposed between the gate electrode layer and a topmost semiconductor layer of the plurality of the semiconductor layers;
a gate spacer disposed adjacent the gate electrode layer and in contact with the IL; and
a blocking structure in contact with a sidewall of each of the plurality of the semiconductor layers, wherein the blocking structure covers an interface defined by the IL and the gate spacer.

13. The semiconductor device structure of claim 12, wherein the IL in contact with the topmost semiconductor layer has a first length, and the topmost semiconductor layer of the plurality of the semiconductor layers has a second length less than the first length.

14. The semiconductor device structure of claim 12, wherein the blocking structure has a rhombus-like shape in a cross-sectional view.

15. The semiconductor device structure of claim 12, wherein the blocking structure is a facetted structure having a plane from the family of {111} planes, the family of {100} planes, the family of {311} planes, or the family of {911} planes.

16. The semiconductor device structure of claim 12, wherein the blocking structure is a boron-doped semiconductor material or a chemical compound involving boron and a semiconductor material.

17. The semiconductor device structure of claim 16, wherein the blocking structure comprises a dopant concentration in a range from about 5E20 atoms/cm³ to about 1E22 atoms/cm³.

18. A method for forming a semiconductor device structure, comprising:
forming a fin structure from a stack of semiconductor layers comprising a plurality of first semiconductor layers and a plurality of second semiconductor layers alternatingly stacked;
forming a sacrificial gate structure over a portion of the fin structure, the sacrificial gate structure comprising a sacrificial gate dielectric and a sacrificial gate electrode layer;
forming a gate spacer on sidewalls of the sacrificial gate structure;
removing portions of the fin structure not covered by the sacrificial gate structure;
subjecting the first and second semiconductor layers to an etch process to form cavities at opposing ends of the second semiconductor layers;
forming a dielectric spacer in the cavities;
forming a blocking structure on opposing ends of the first semiconductor layers, wherein the blocking structure covers an interface defined by the sacrificial gate dielectric and the sacrificial gate electrode layer;
forming a source/drain feature on opposite sides of the sacrificial gate structure, the source/drain feature being in contact with the blocking structure;
removing the sacrificial gate structure and the plurality of second semiconductor layers to expose portions of the plurality of first semiconductor layers and the blocking structure; and
forming a gate electrode layer to surround the exposed portion of the plurality of first semiconductor layers.

19. The method of claim 18, wherein the blocking structure is a boron-doped semiconductor material or a chemical compound involving boron and a semiconductor material.

20. The method of claim 18, wherein subjecting the first and second semiconductor layers to an etch process removes edge portions of the second semiconductor layers are removed by a first lateral distance and edge portions of the first semiconductor layers are removed by a second lateral distance less than the first lateral distance.
